(19) United States
(12) Patent Application Publication
(10) Pub. No.: US 2011/0182125 A1
(43) Pub. Date: Jul. 28, 2011

(54) SEMICONDUCTOR MEMORY DEVICE, SEMICONDUCTOR DEVICE, AND METHOD OF DATA ERASE IN THE SEMICONDUCTOR MEMORY DEVICE

(75) Inventors: Mikihiko ITOH, Ota-ku (JP); Takeshi Nakano, Kawasaki-shi (JP); Michio Nakagawa, Yokohama-shi (JP)

(73) Assignee: KABUSHIKI KAISHA TOSHIBA, Tokyo (JP)

(21) Appl. No.: 12/883,474

(22) Filed: Sep. 16, 2010

(30) Foreign Application Priority Data
Jan. 27, 2010 (JP) 2010-015731

(51) Int. Cl. G11C 16/16

(52) U.S. Cl. 365/185.33

(57) ABSTRACT

A semiconductor memory device in accordance with an embodiment comprises a memory cell array and an erase voltage generating circuit. The memory cell array is configured as an arrangement of nonvolatile memory cells. The erase voltage generating circuit is configured to generate an erase voltage for performing data erase of the memory cell array. The erase voltage generating circuit is configured to set, in a data erase mode where the erase voltage is applied to a selected region of the memory cell array in a plurality of erase cycles, a rise waveform of the erase voltage in an initial stage of the plurality of erase cycles to be less steep than a rise waveform of the erase voltage in subsequent cycles.

### CROSS-REFERENCE TO RELATED APPLICATIONS

This application is based upon and claims the benefit of priority from the prior Japanese Patent Application No. 2010-15731, filed on Jan. 27, 2010, the entire contents of which are incorporated herein by reference.

### BACKGROUND

1. Field

Embodiments described in the present specification relate to a semiconductor memory device having nonvolatile memory cells, a semi conduct or device employing the nonvolatile memory cells, and a method of data erase in the semiconductor memory device, in particular, to improvements in a data erase operation in the semiconductor memory device.

2. Description of the Related Art

NAND flash memory, which is one kind of nonvolatile semiconductor memory device, is configured using memory cells each structured by a MOS transistor having a floating gate FG. The floating gate FG is disposed on a channel region with a tunnel insulating film interposed therebetween, and a control gate CG is further stacked on the floating gate FG with an inter-gate insulating film interposed therebetween. The control gates CG are commonly connected to a word line in one direction within a cell array.

In this flash memory, write of data is performed by injecting electrons into the floating gate FG via the tunnel insulating film, and erase of data is performed by discharging those electrons. Binary data storage is performed, for example, by assuming a negative threshold state (erase state) in which the electrons are discharged from the floating gate to be data “1”, and assuming a positive threshold state (write state) in which the electrons are injected into the floating gate to be data “0”. Multilevel data storage is made possible by setting multiple levels of write threshold states.

In recent years, along with advances in miniaturization and increasingly high integration of NAND flash memory, there have occurred problems of deterioration in data retention characteristics of memory cells and of deterioration in memory cell characteristics due to repeated write and erase. For example, a method of data erase is known in which an erase voltage application operation and a verify operation for confirming an erase state are repeated on multiple occasions. It is pointed out that, if data erase is performed repeatedly using this method, electrons become trapped in an interface state formed in the tunnel insulating film, whereby cell characteristics deteriorate (cell current decreases).

### BRIEF DESCRIPTION OF THE DRAWINGS

FIG. 1 is a block diagram showing a schematic configuration of a NAND flash memory in accordance with an embodiment.

FIG. 2 is an equivalent circuit diagram of a memory cell array in the same flash memory.

FIG. 3 is a view showing a configuration of an erase voltage generating circuit in the same flash memory.

FIG. 4 is a view showing a configuration of a VPP-dedicated charge pump in the same erase voltage generating circuit.

FIG. 5 is a view showing a configuration of a VPP-dedicated clock generating circuit in the same erase voltage generating circuit.

FIG. 6 is a view showing a configuration of a VPP-dedicated voltage detecting circuit in the same erase voltage generating circuit.

FIG. 7 is a view showing waveforms in operation of the VPP-dedicated charge pump.

FIG. 8 is a view showing a configuration of a VMM-dedicated charge pump.

FIG. 9 is a view showing a configuration of a VMM-dedicated clock generating circuit.

FIG. 10 is a view showing a configuration of a VMM-dedicated voltage detecting circuit.

FIG. 11 is a view showing waveforms in operation of the VMM-dedicated charge pump.

FIG. 12 is a view showing a comparison of capabilities of the VPP-dedicated charge pump and the VMM-dedicated charge pump.

FIG. 13 is a view showing waveforms in an erase operation according to embodiment 1.

FIG. 14 is a view showing waveforms in an erase operation according to embodiment 2.

FIG. 15 is a view showing a configuration of an erase voltage generating circuit employed in embodiment 3.

FIG. 16 is a view showing a configuration of a clock divider circuit in the same erase voltage generating circuit.

FIG. 17 is a view showing a configuration of a clock selector circuit in the same erase voltage generating circuit.

FIG. 18 is a view showing waveforms in operation of the clock divider circuit.

FIG. 19 is a view showing boost capabilities of the VMM-dedicated charge pump in cases where frequency division is performed and where frequency division is not performed.

FIG. 20 is a view showing waveforms in an erase operation according to embodiment 3.

FIG. 21 is a view showing waveforms in an erase operation according to embodiment 4.

FIG. 22 is a view showing a configuration of an erase voltage generating circuit employed in embodiment 5.

FIG. 23 is a view showing a configuration of a VMM1-dedicated and VMM2-dedicated charge pump employed in the same erase voltage generating circuit.

FIG. 24 is a view showing boost capability of the same charge pump.

FIG. 25 is a view showing waveforms in an erase operation according to embodiment 5.

FIG. 26 is a view showing waveforms in an erase operation according to embodiment 6.

FIG. 27 is a view showing waveforms in an erase operation of a comparative example.

FIG. 28 is a view showing a state of a memory cell and a well potential in a first erase operation (Loop 1).

FIG. 29 is a view showing a state of a memory cell and a well potential in a fourth erase operation (Loop 4).

### DETAILED DESCRIPTION

A semiconductor memory device in accordance with an embodiment comprises a memory cell array, and an erase voltage generating circuit. The memory cell array is configured as an arrangement of nonvolatile memory cells. The erase voltage generating circuit is configured to generate an erase voltage for performing data erase of the memory cell array. The erase voltage generating circuit is configured to set, in a data erase mode where the erase voltage is applied to a selected region of the memory cell array in a plurality of erase cycles, a rise waveform of the erase voltage in an initial stage of the plurality of erase cycles to be less steep than a rise waveform of the erase voltage in subsequent cycles.

A semiconductor device in accordance with another embodiment comprises an erase voltage generating circuit configured to generate an erase voltage for performing data erase of a memory cell array, the memory cell array configured as an arrangement of nonvolatile memory cells. The erase voltage generating circuit is configured to set, in a data erase mode where the erase voltage is applied to a selected region of the memory cell array in a plurality of erase cycles, a rise waveform of the erase voltage in an initial stage of the plurality of erase cycles to be less steep than a rise waveform of the erase voltage in subsequent cycles.

A method of data erase in a semiconductor memory device in accordance with yet another embodiment comprises generating an erase voltage for performing data erase of a memory cell array, the memory cell array being configured as an arrangement of nonvolatile memory cells, and, in a data erase mode where the erase voltage is applied to a selected region of the memory cell array in a plurality of erase cycles, setting a rise waveform of the erase voltage in an initial stage of the plurality of erase cycles to be less steep than a rise waveform of the erase voltage in subsequent cycles.

A NAND flash memory according to an embodiment is described below with reference to the drawings.

[Flash Memory Configuration]

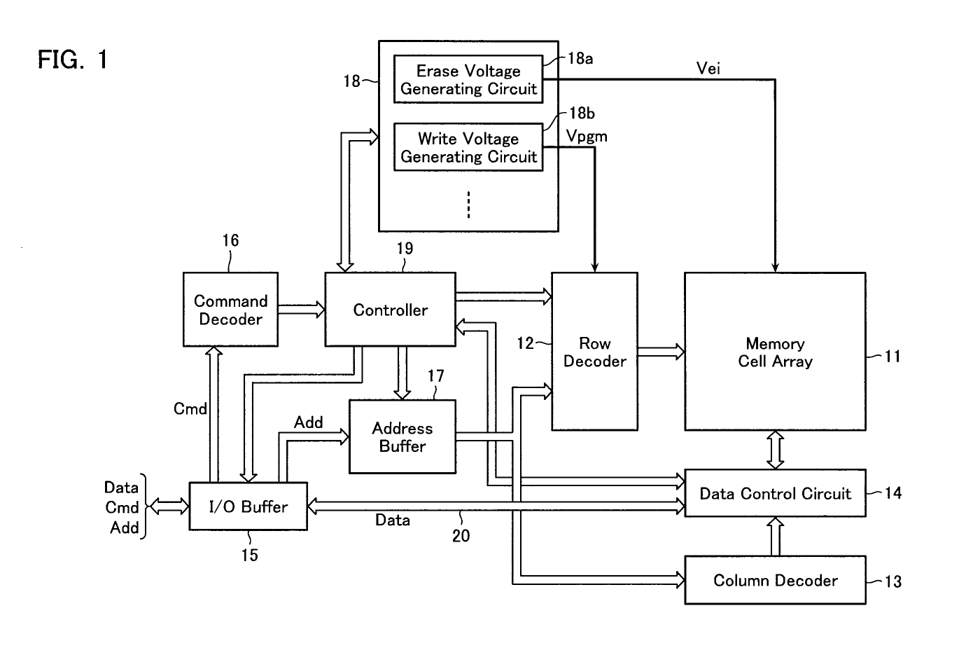

FIG. 1 is a block diagram showing a schematic configuration of a NAND flash memory. This NAND flash memory includes a memory cell array 11 configured as an arrangement of nonvolatile memory cells, a row decoder 12 including a word line driver, a column decoder 13, and a data control circuit 14.

An address Add is loaded into an address buffer 17 via an input/output buffer 15, and a row address and column address are transferred to the row decoder 12 and column decoder 13, respectively. A command Cmd is passed via the input/output buffer 15 to a command decoder 16 where it is decoded and then sent to a controller 19 for use in operation control. Data is transferred between the data control circuit 14 and external via the input/output buffer 15 and a data bus 20.

The controller 19 performs read control, and sequence control of write and erase in the memory cell array 11. The controller 19 is provided with an internal voltage generating circuit 18 for generating various kinds of internal voltages according to operation modes of read, write, and erase.

Specifically, the internal voltage generating circuit 18 includes an erase voltage generating circuit 18a, a write voltage generating circuit 18b, and other kinds of boost circuits. The internal voltage generating circuit 18 is controlled by the controller 19 in accordance with the command Cmd, and is configured to generate an erase voltage Vei applied to a P-type well of the cell array, and a write voltage Vpgm applied to a selected word line.

The nonvolatile memory cells are disposed in a matrix in the memory cell array 11. Each of the memory cells has a MOS transistor structure in which a floating gate is formed on a channel region with a tunnel insulating film interposed therebetween, and a control gate is stacked on the floating gate with an inter-gate insulating film interposed therebetween.

The data control circuit 14 comprises a sense amplifier circuit for detecting and amplifying data read from the memory cells in the memory cell array 11, and is configured to temporarily store write data supplied from the input/output buffer 15 and to perform bit line voltage control during write. The row decoder decodes a row address signal supplied from the address buffer 17 to perform selection and drive of word lines in the memory cell array 11. The column decoder 13 decodes a column address signal supplied from the address buffer 17 to perform selection of bit lines in the memory cell array 11.

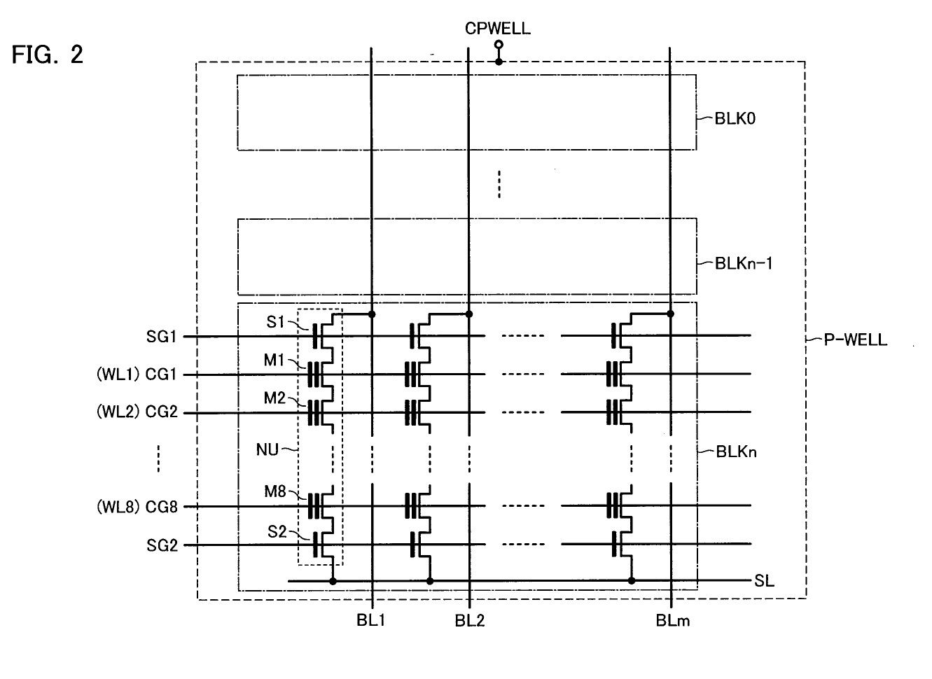

FIG. 2 shows an equivalent circuit diagram of the memory cell array 11. Control gate lines CG1, CG2, . . . , CG8, select gate lines SG1 and SG2, and a source line SL are disposed, respectively, in a row direction, and bit lines BL1, BL2, . . . , BLm are disposed in a column direction. Memory cells M1, M2, . . . , M8 and select gate transistors S1 and S2 are disposed at intersections of each of the control gate lines and bit lines.

Now, an example is shown in which eight memory cells M1-M8 are connected in series sharing sources and drains to configure a NAND string NU. The NAND string NU has one end connected via the select gate transistor S1 to a bit line, and the other end connected via the select gate transistor S2 to the source line SL.

In the NAND string NU, control gates of each of the cells M1, M2, . . . , M8 are connected to the control gate lines CG1, CG2, . . . , CG8, and gates of the select gate transistors S1 and S2 are connected to the select gate lines SG1 and SG2, respectively. The control gate lines CG1, CG2, . . . , CG8 configure word lines WL1, WL2, . . . , WL8.

An assembly of NAND strings NU aligned in a word line direction is a block configuring a unit of data erase, and there are a plurality of blocks BLK0-BLKn disposed in a bit line direction. These blocks are formed within one P-type well. The source line SL is connected to a common source potential Vs generated by a peripheral circuit (not shown).

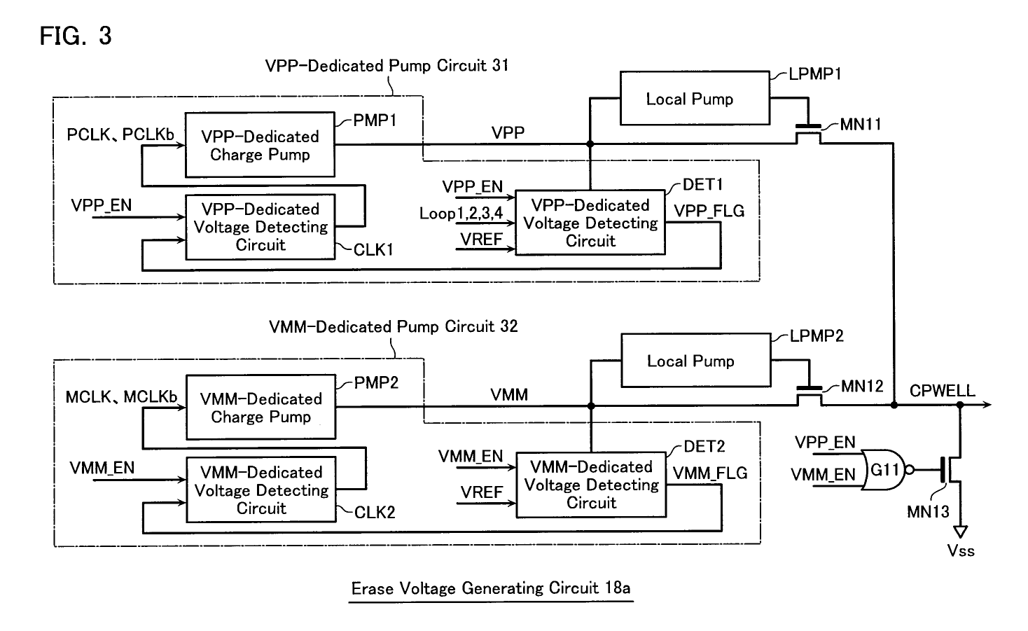

FIG. 3 shows a configuration of the erase voltage generating circuit 18a. A VPP-dedicated boost pump circuit 31 and a VMM-dedicated boost pump circuit 32 are provided in parallel in the erase voltage generating circuit 18a, the VPP-dedicated boost pump circuit 31 and the VMM-dedicated boost pump circuit 32 having different capabilities. That is, the VPP-dedicated pump circuit 31 and the VMM-dedicated pump circuit 32 are for generating, respectively, a boost voltage VPP and a boost voltage VMM satisfying VPP>VMM.

The VPP-dedicated pump circuit 31 includes: a charge pump PMP1 for generating the voltage VPP; a clock generating circuit CLK1 for driving the charge pump PMP1; and a voltage detecting circuit DET1. Moreover, there is a local pump LPMP1 for boosting the gate of an NMOS transistor MN11, the NMOS transistor MN11 supplying the voltage VPP to a terminal CPWELL of the P-type well formed in the memory cell.

The VMM-dedicated pump circuit 32 includes: a charge pump PMP2 for generating the voltage VMM; a clock generating circuit CLK2 for driving the charge pump PMP2; and a voltage detecting circuit DET2, and includes, moreover, a local pump LPMP2 for boosting the gate of an NMOS transistor MN12.

An NMOS transistor MN13 is for resetting, being configured to short a voltage of the terminal CPWELL to a ground voltage Vss except during the erase operation. A NOR logic circuit G11 is provided to control the gate of the NMOS transistor MN13.

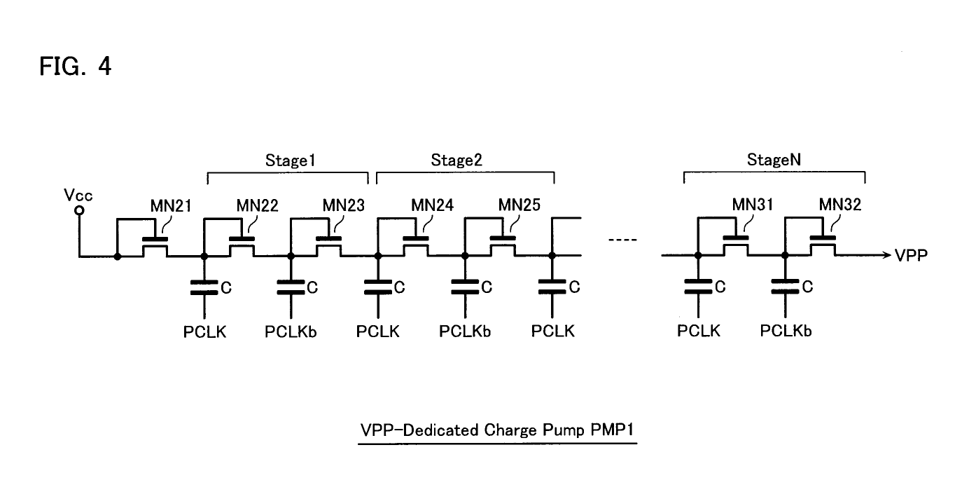

FIG. 4 shows a configuration of the VPP-dedicated charge pump circuit PMP1. The charge pump PMP1 is configured having a plurality of stages of diode-connected NMOS transistors connected in series between a power supply voltage Vcc and a VPP terminal, pumping capacitors C being connected to each of connecting nodes. Complementary clocks PCLK and PCLKb are alternately applied to the terminals of each of the capacitors C.

NMOS transistors MN22 and MN23 are assumed to form one boost unit (transfer stage) “Stage 1”, subsequent NMOS transistors MN24 and MN25 are assumed to form a boost unit “Stage 2”, and similarly thereafter, whereby, for example, N stages of boost units are connected in series.

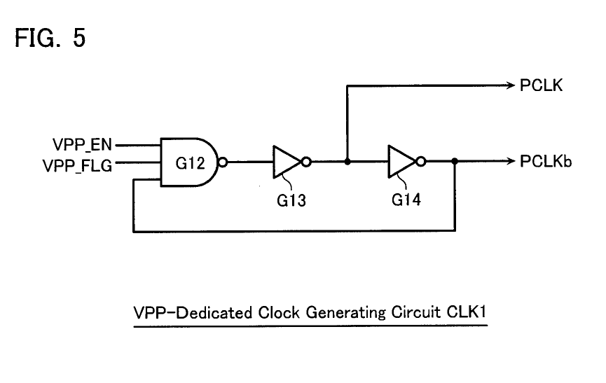

FIG. 5 shows a configuration of the VPP-dedicated clock generating circuit CLK1. The VPP-dedicated clock generating circuit CLK1 is configured by a NAND gate G12, an inverter G13, and an inverter G14. The NAND gate G12 has as inputs a VPP-dedicated pump activating signal VPP_EN, a detecting signal VPP_FLG from the VPP-dedicated voltage detecting circuit DET1, and an inverted signal PCLKb of the VPP-dedicated pump clock PCLK. The inverter G13 has as input the output of the NAND gate G12 and outputting the clock PCLK. The inverter G14 has as input the clock PCLK and outputting the inverted signal PCLKb.

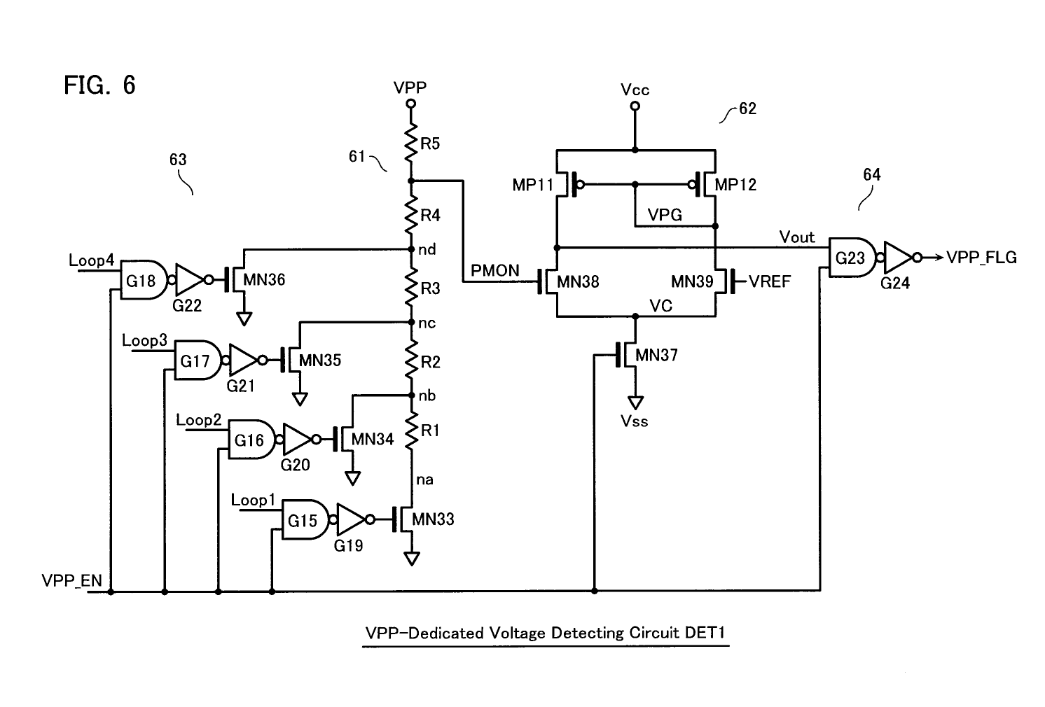

FIG. 6 shows a configuration of the VPP-dedicated voltage detecting circuit DET1. The voltage detecting circuit DET1 includes a resistance voltage divider circuit 61, and a differential amplifier 62. The resistance voltage divider circuit 61 is configured by resistances R1-R5 connected in series between an output terminal (voltage VPP) of the charge pump PMP1 and the voltage Vss via an NMOS transistor MN33. The differential amplifier 62 is configured to compare an output monitor voltage PMON of the resistance voltage divider circuit 61 with a reference voltage VREF. The differential amplifier 62 is configured by a current mirror load formed from PMOS transistors MP11 and MP12 and a driver formed from NMOS transistors MN38 and MN39.

A switching control circuit 63 is provided for switching the monitor voltage PMON in accordance with an erase loop. That is, the switching control circuit 63 includes shorting NMOS transistors MN33, MN34, MN35, and MN36 for respectively setting nodes na, nb, nc, and nd of the resistance voltage divider circuit 61 to the voltage Vss, and NAND gates G15, G16, G17, and G18 for selectively driving each of these transistors MN33, MN34, MN35, and MN36 by loop signals Loop1, Loop2, Loop3, and Loop4 indicating number of erase operation.

The gate of the NMOS transistor MN33 interposed between the resistance voltage divider circuit 61 and the voltage Vss is driven by the NAND gate G15 inputted with the loop signal Loop1. The NAND gates G15-G18, in addition to being inputted respectively with the loop signals Loop1-Loop4, are also commonly inputted with the activating signal VPP_EN.

Such a configuration allows a setting voltage value of the voltage VPP to be changed in accordance with the erase cycle. That is, in the case of a first erase, Loop1=“H” causes the NMOS transistor MN33 to be turned on, and the connection node na between the resistance R1 and the NMOS transistor MN33 to be set to the voltage Vss. Consequently, the monitor voltage PMON becomes PMON=VPP×R5/(R1+R2+R3+R4+R5). In the case of a second erase, Loop2=″H″ causes the connection node nb between the resistances R1 and R2 to be set to the voltage Vss, whereby the monitor voltage PMON becomes VPP×R5/(R2+R3+R4+R5). Similarly thereafter, with each increment in the number of erases, the resistance voltage division ratio falls, leading to a lowering of the monitor voltage PMON.

If the monitor voltage PMON is lower than the reference voltage VREF, the differential amplifier output is Vout=“H”, and if the monitor voltage PMON is higher than the reference voltage VREF, the differential amplifier output is Vout=“L”. The output voltage Vout is output as the detecting signal VPP_FLG via an output gate 64.

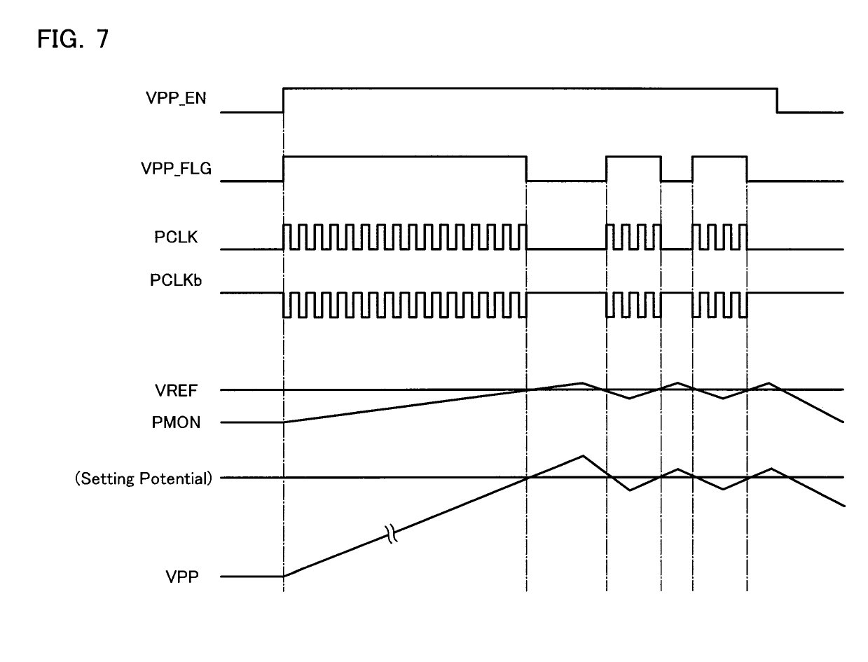

FIG. 7 shows a waveform diagram of operation of the VPP-dedicated pump and of the voltage VPP. While the activating signal VPP_EN is “L”, the VPP-dedicated pump does not operate. When VPP_EN becomes “H”, the VPP-dedicated voltage detecting circuit DET1 becomes operative. When the monitor voltage PMON is lower than the reference voltage VREF, the detecting signal VPP_FLG of “H” is outputted. This causes the VPP-dedicated clock generating circuit CLK1 to operate, whereby the complementary clock signals PCLK/PCLKb are outputted.

The VPP-dedicated charge pump PMP1 receives these clock signals PCLK/PCLKb to perform a boost operation, whereby the voltage VPP rises. When the voltage VPP exceeds a setting potential, the monitor voltage PMON becomes higher than the reference voltage VREF, and the detecting signal VPP_FLG shifts to “L”.

In this state, the clock signals PCLK/PCLKb attain fixed values of “L”/“H”, whereby the charge pump suspends the boost operation. The voltage VPP gradually falls due to leak current and so on, and when the voltage VPP falls below the setting potential, the detecting signal VPP_FLG becomes “H”, whereby the VPP-dedicated charge pump PMP1 resumes the boost operation.

In such a way, during the period when the activating signal VPP_EN is “H”, the charge pump repeats operation and suspension thereby maintaining VPP at the setting voltage, and when the activating signal VPP_EN shifts to “L”, the charge pump stops the boost operation.

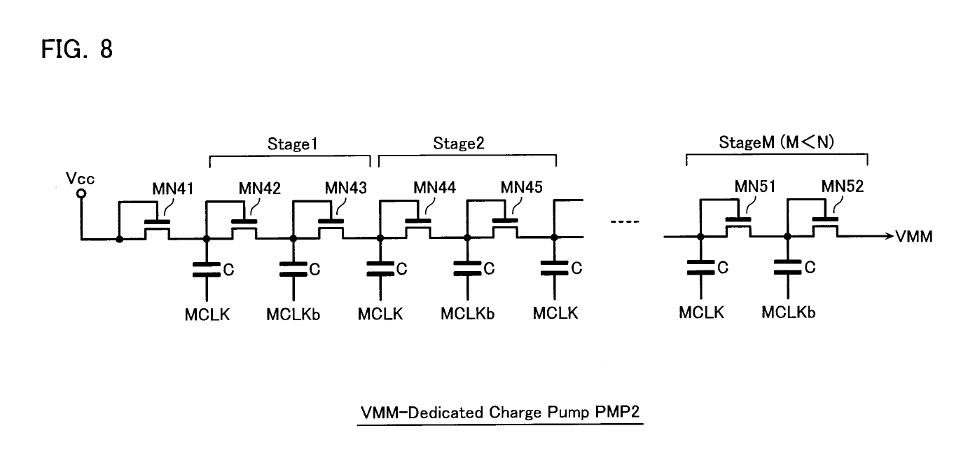

FIG. 8 shows a configuration of the VMM-dedicated charge pump PMP2. The VMM-dedicated charge pump PMP2 has a basic configuration similar to that of the VPP-dedicated charge pump PMP1 shown in FIG. 4, but differs in having a smaller number M (M<N) of stages of boost units connected in series.

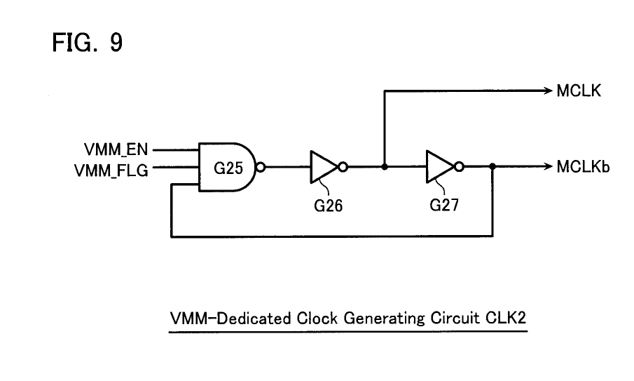

FIG. 9 shows a configuration of the VMM-dedicated clock generating circuit CLK2. This circuit is the same as that of the VPP-dedicated clock generating circuit CLK1 shown in FIG. 5.

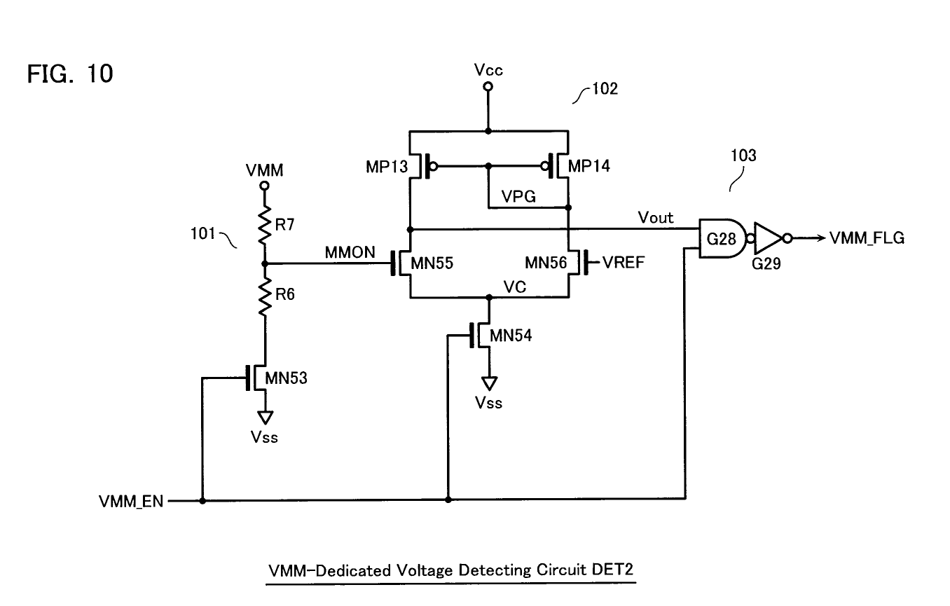

FIG. 10 shows the VMM-dedicated voltage detecting circuit DET2. The VMM-dedicated voltage detecting circuit DET2 has a basic configuration similar to that of the VPP-dedicated voltage detecting circuit DET1 shown in FIG. 6, but includes a resistance voltage divider circuit 101 configured to output a monitor voltage MMON, a differential amplifier 102 for comparing the monitor voltage MMON with the reference voltage VREF, and an output gate 103. The differential amplifier 102 is the same as the differential amplifier 62 in FIG. 6.

Since the monitor voltage MMON is fixed at the voltage VMM irrespective of the number of erases operation, the resistance voltage divider circuit 101 is configured by two resistances R6 and R7 connected in series between the voltage VMM and the voltage Vss, and an NMOS transistor MN53. There is no monitor voltage switching control circuit.

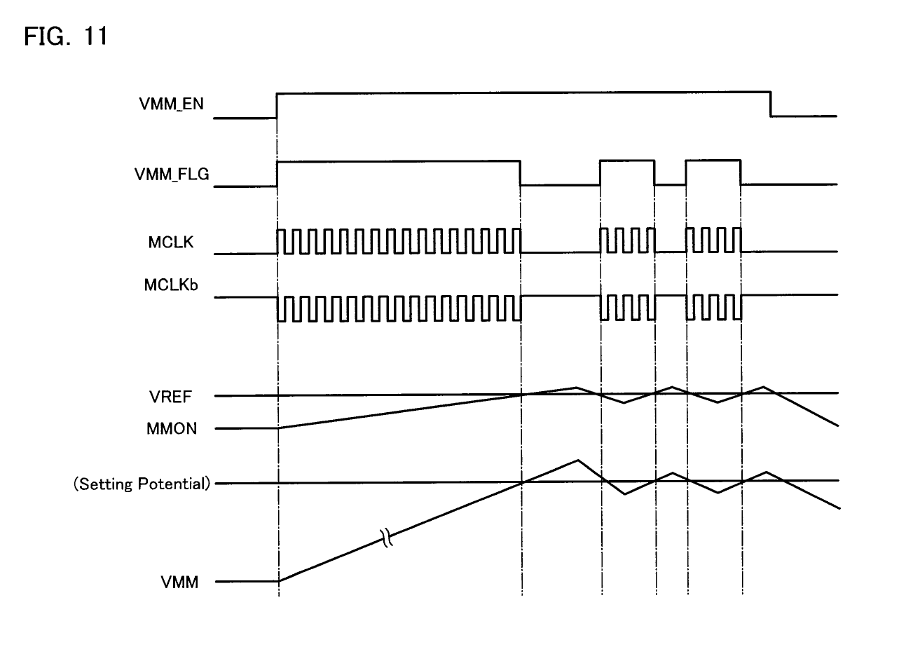

FIG. 11 shows a waveform diagram of operation of the VMM-dedicated pump and of the voltage VMM. Operation itself of the VMM-dedicated pump PMP2 is the same as operation of the VPP-dedicated pump PMP1, and a detailed description is thus omitted.

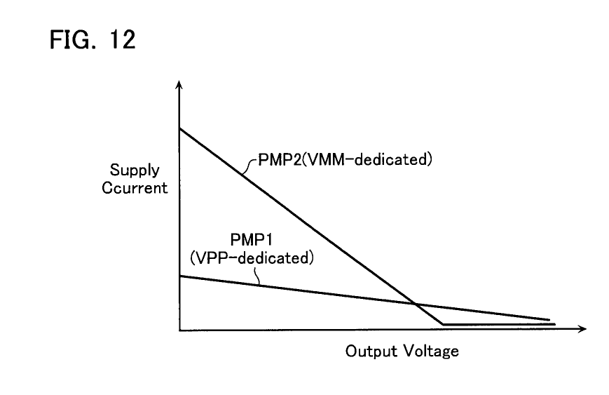

FIG. 12 shows a supply current capability with respect to output voltage for the VPP-dedicated charge pump PMP1 and the VMM-dedicated charge pump PMP2. The number of stages of boost units is N for the VPP-dedicated charge pump PMP1 and M (M<N) for the VMM-dedicated charge pump PMP2. Accordingly, when output voltage is low, the supply current of the VMM-dedicated pump is greater. When the output voltage is high, only the VPP-dedicated pump can supply current, and the VMM-dedicated pump almost loses capability of supplying a current. That is, in an initial stage of the boost operation, a high-speed boost is performed by the VMM-dedicated pump. As the voltage rises, the boost capability of the VMM-dedicated pump falls. When the output voltage gets close to the voltage VPP, only the VPP-dedicated pump operates.

[Basic Data Erase Mode (Comparative Example)]

A basic data erase operation in a comparative example comprising the aforementioned erase voltage generating circuit is described. Generally, the pair of boost pump circuits of different capabilities described in FIG. 12 are utilized to perform boosting of the erase voltage mainly by the VMM-dedicated charge pump PMP2 in a low erase voltage range, and to perform boosting by the VPP-dedicated charge pump PMP1 in a high erase voltage range. Utilizing this kind of boost operation enables the rise time of the erase voltage to be shortened, and the erase time to be shortened.

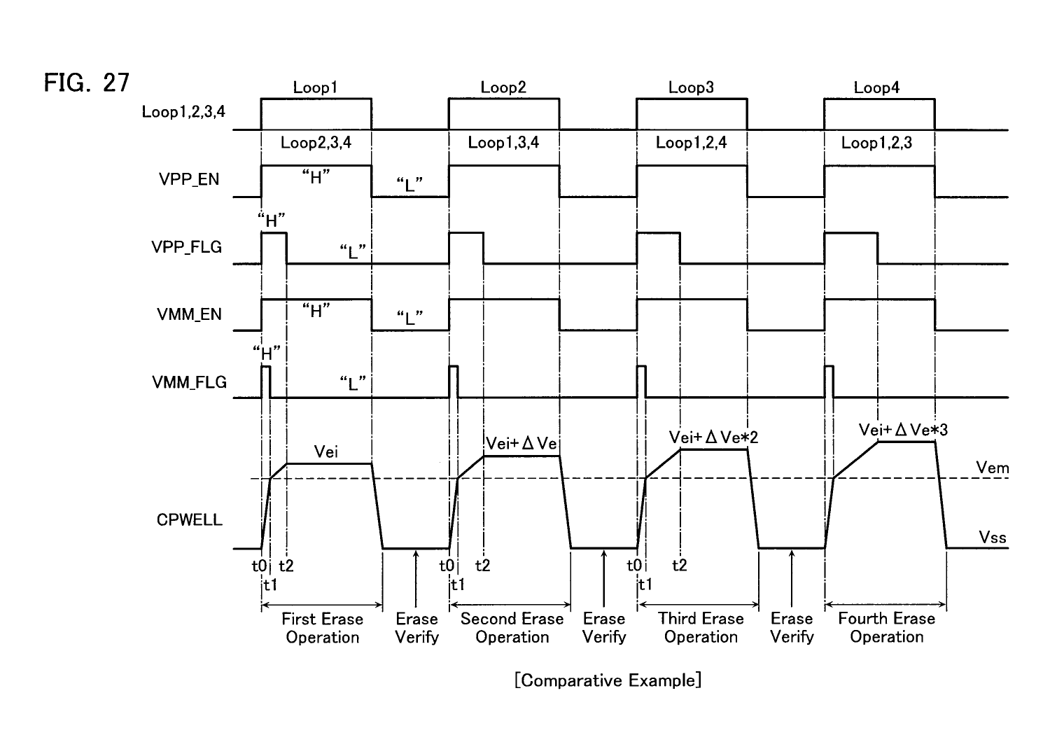

FIG. 27 shows how this erase voltage generation works. Now, an example is shown in which the erase voltage application operation is completed in four cycles (four loops Loop1-Loop4). At erase operation start time t0 for each cycle, the activating signals VPP_EN and VMM_EN outputted from the controller 19 attain “H”, and the VPP-dedicated charge pump PMP1 and the VMM-dedicated charge pump PMP2 both start to operate. When the potential of the terminal CPWELL of the P-well where the memory cells are formed exceeds a certain setting voltage Vem, the detecting signal VMM_FLG of the VMM-dedicated detecting circuit DET2 shifts to “L”. At timing t1 of that transition, the VMM-dedicated charge pump PMP2 suspends operation. Boosting after time t1 to the setting voltage corresponding to each of the erase cycles (Vei, Vei+ΔVe, Vei+ΔVex2, Vei+ΔVex3) is performed only by the VPP-dedicated charge pump PMP1.

When the potential of the terminal CPWELL exceeds the setting voltage (timing t2), the detecting signal VPP_FLG of the VPP-dedicated detecting circuit DET1 transits to “L”, and the VPP-dedicated charge pump PMP1 also suspends operation. Such an operation causes the terminal CPWELL to be applied with an erase voltage stepped up in accordance with the erase cycle number (Vei, Vei+ΔVe, Vei+ΔVex2, Vei+ΔVex3).

Meanwhile, all control gates CG (all word lines WL) within a selected block subject to erase are applied with the voltage Vss. The difference between the voltage Vss of the control gate CG and the erase voltage of the P-well causes the electrons injected into the floating gate FG during write to be discharged via the tunnel insulating film.

Note that between each of the erase loops, an erase verify operation is usually performed to confirm. However, sequence control omitting at least a part of the erase verify operation is also possible in view of a high-speed erase operation. For example, the erase verify operation in the initial stage of the erase sequence is sometimes omitted.

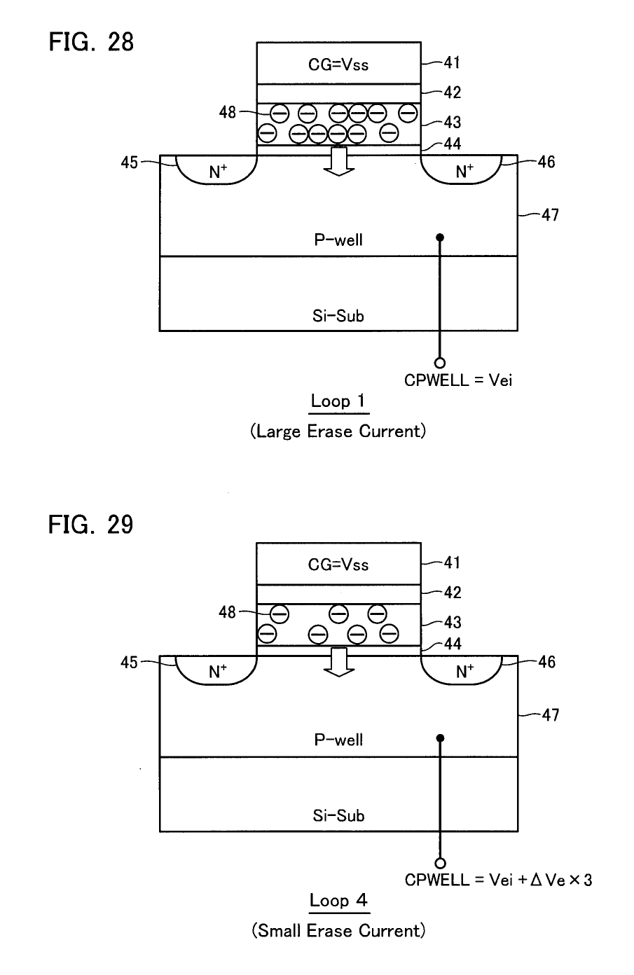

Problems of the erase operation of memory cells by this kind of ordinary data erase mode are described using FIGS. 28 and 29. FIGS. 28 and 29 show schematically a cell erase operation by a first loop Loop1 and by a fourth loop Loop4, respectively.

In the first loop Loop1, erase is performed in a state where the memory cell is written with data, that is, in a state where a large number of electrons 48 are injected into a floating gate (FG) 43. Therefore, if the voltage Vss is applied to a control gate (CG) 41 and the erase voltage Vei is applied to the P-well terminal CPWELL, a large electric field is applied to a tunnel insulating film 44, whereby a large tunnel current (erase current) flows from the floating gate via the tunnel insulating film 44 to an inter-drain/source 45/46 channel region of the P-well 47.

With advancing erase loops, the erase voltage applied to the terminal CPWELL increases, whereby electrons are discharged from the floating gate 43. In the fourth loop Loop4 of the erase operation, the erase voltage applied to the terminal CPWELL is Vei+ΔVex3, which is a voltage higher than that of the first through third loops. However, the electrons 48 remaining in the floating gate 43, which are shown schematically in FIG. 29, are fewer than at first (FIG. 28). As a result, the amount of electrons that cross the tunnel insulating film 44 is reduced.

As described above, a large erase current flows in the first loop of an erase voltage application operation performed in a plurality of cycles. This large erase current flow is thought to be the principal cause of tunnel insulating film deterioration arising from the erase operation. That is, in the first loop of the erase operation, an interface state is formed in the tunnel insulating film and electrons are trapped in this interface state, which makes it difficult for subsequent erase current to flow and, moreover, is a cause of deterioration in cell characteristics whereby threshold of the memory cell in the erase state does not fall sufficiently.

Described below are embodiments that enable deterioration of memory cell characteristics in the erase operation to be suppressed without impairing high speed of the erase operation.

### Embodiment 1

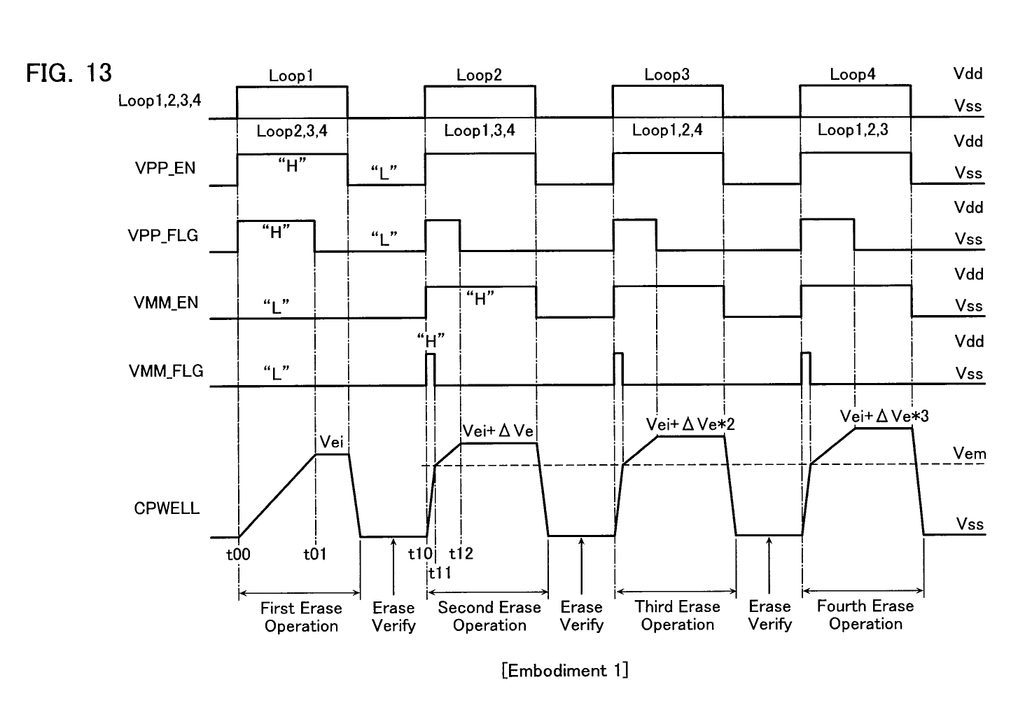

FIG. 13 shows, by correspondence with FIG. 27, how erase voltage generation is performed in the data erase mode in accordance with embodiment 1. The erase voltage generating circuit 18a is as described above and has a control method that differs from the case of the erase mode of FIG. 27. In FIG. 13, the case is shown where erase is performed in four erase loops (Loop1-Loop4) to correspond with FIG. 27.

It is assumed here that the signals Loop1-Loop4 indicating the number of erase operation, the VPP-dedicated pump activating signal VPP_EN, and the VMM-dedicated pump activating signal VMM_EN are generated by the controller 19.

Prior to the erase operation, the VPP-dedicated pump activating signal VPP_EN and the VMM-dedicated pump activating signal VMM_EN are both “L”, and the voltage of the terminal CPWELL is connected to the voltage Vss by the OR gate G11 and the transistor MN13. When the first erase operation is started, the VPP-dedicated pump activating signal VPP_EN attains “H” and the MOS transistor MN13 is thus turned off, whereby the VPP-dedicated pump PMP1 starts the boost operation (timing t00).

On the other hand, even though the first erase operation is started, the VMM-dedicated pump activating signal VMM_EN maintains “L”, and the VMM-dedicated pump PMP2 remains suspended. That is, the first erase operation is performed only by the VPP-dedicated pump PMP1. Moreover, in the first erase operation, only Loop1 of the loop signals is “H”, and the remaining Loop2-Loop4 are “L”. In the VPP-dedicated voltage detecting circuit DET1, the NMOS transistor MN33 is turned on due to the NAND gate G15, which has as inputs the activating signal VPP_EN and Loop1, and the inverter G19. In addition, the NMOS transistor MN37 is turned on.

This causes the detecting circuit DET1 to output the detecting signal VPP_FLG=“H” so as to boost the voltage VPP until the setting voltage is attained. The boost potential VPP is supplied, via the NMOS transistor MN11 that has its gate applied with a boost potential by the local pump LPMP1, to the P-well terminal CPWELL formed in the memory cell. When the voltage VPP and the potential of the terminal CPWELL reach the setting potential Vei, operation of the VPP-dedicated voltage detecting circuit DET1 causes VPP_FLG to attain “L”, whereby the boost operation is suspended (timing t01).

As shown in FIG. 12, while output voltage is low, the supply current of the VPP-dedicated pump PMP1 is less than the supply current of the VMM-dedicated pump PMP2. Consequently, as shown in FIG. 13, in the first erase operation, the rise waveform of the potential of the terminal CPWELL is less steep than that of the comparative example shown in FIG. 27. As a result, electron discharge from the floating gate of the cell during the erase operation is suppressed. In other words, the amount of current crossing the tunnel insulating film (erase current amount) in the initial stage of the erase operation is reduced, thereby enabling deterioration of the tunnel insulating film to be suppressed.

In the second and subsequent erase operations, the amount of current crossing the tunnel insulating film is less than in the first erase operation. There is thus no need to suppress boost speed of the erase voltage, and the boost operation is one having a conventional rise waveform with no reduction in steepness. Specifically, the second erase operation is described. Prior to the erase operation, the terminal CPWELL is connected to the voltage Vss.

When the second erase operation is started, the VPP-dedicated pump activating signal VPP_EN attains “H” and the MOS transistor MN13 is thus turned off. Consequently, the VPP-dedicated pump PMP1 starts the boost operation (timing t10). Simultaneously, the VMM-dedicated pump activating signal VMM_EN attains “H”, whereby the VMM-dedicated pump PMP2 also starts the boost operation.

In the VMM-dedicated voltage detecting circuit DET2, the NMOS transistor MN53 and MN54 are turned on due to the activating signal VMM_EN attaining “H”. This causes the voltage detecting circuit DET2 to be activated and to output the detecting signal VMM_FLG=“H” so as to boost the voltage VMM until the setting voltage Vem is attained.

The boost potential VMM is supplied, via the NMOS transistor MN12 that has its gate applied with a boost potential by the local pump LPMP2, to the terminal CPWELL. When the voltage VMM reaches the setting voltage Vem, the VMM-dedicated voltage detecting circuit DET2 causes VMM_FLG to attain “L”, whereby the VMM-dedicated pump PMP2 suspends the boost operation (timing t11).

However, since the erase voltage is lower than the setting voltage Vei+ΔVe, the output VPP_FLG of the VPP-dedicated voltage detecting circuit DET1 maintains “H”. Accordingly, subsequent to suspension of the VMM-dedicated pump PMP2, boosting of the erase voltage until the setting voltage Vei+Ve is performed only by the VPP-dedicated pump PMP1. The boost potential VPP is supplied, via the NMOS transistor MN11 that has its gate applied with a boost potential by the local pump LPMP1, to the terminal CPWELL.

When the erase voltage reaches the setting voltage Vei+Δ Ve, the VPP_FLG attains “L”, whereby the VPP-dedicated pump PMP1 suspends the boost operation (timing t12).

As shown in FIG. 12, when output voltage is low, the supply current of the VMM-dedicated pump PMP2 is greater than the supply current of the VPP-dedicated pump PMP1. Consequently, as shown in FIG. 13, in the second erase operation, the boost speed of the potential of the terminal CPWELL to the setting potential Vem is faster than in the first erase operation. In the second erase operation, electrons not discharged in the first erase operation are discharged, and it is thus required to boost the potential of the terminal CPWELL to the voltage Vei+ΔVe which is higher than in the first erase operation.

There is a possibility that time taken for the second boost operation is longer than that taken for the first boost operation, but the present embodiment allows extension of the time taken to be suppressed. The third and fourth erase operations are similar to the second erase operation.

Such an operation allows the present embodiment to discharge the electrons of the floating gate slowly during the first erase operation which is the operation that causes most deterioration of the tunnel insulating film. As a result, the amount of current that crosses the tunnel insulating film is maintained small, whereby deterioration of the tunnel insulating film can be minimized. On the other hand, extension of the erase operation time in the second and subsequent erase operations can be suppressed, enabling the time taken for the erase operation to be maintained equal to that of a conventional erase operation. That is, it is possible to suppress deterioration of cell characteristics accompanying the erase operation, without impairing high speed of the erase operation.

### Embodiment 2

There are cases where, in the first erase operation, almost no electrons in the floating gate FG are discharged, such as when the erase voltage Vei is set low, or when the erase time is short. During the second erase operation, the erase voltage is set to the voltage Vei+ΔVe which is higher than the voltage Vei of the first erase operation, and the electrons thus become more easily discharged. Consequently, there is a possibility that the amount of current crossing the tunnel insulating film during the second erase operation becomes large, whereby the tunnel insulating film deteriorates.

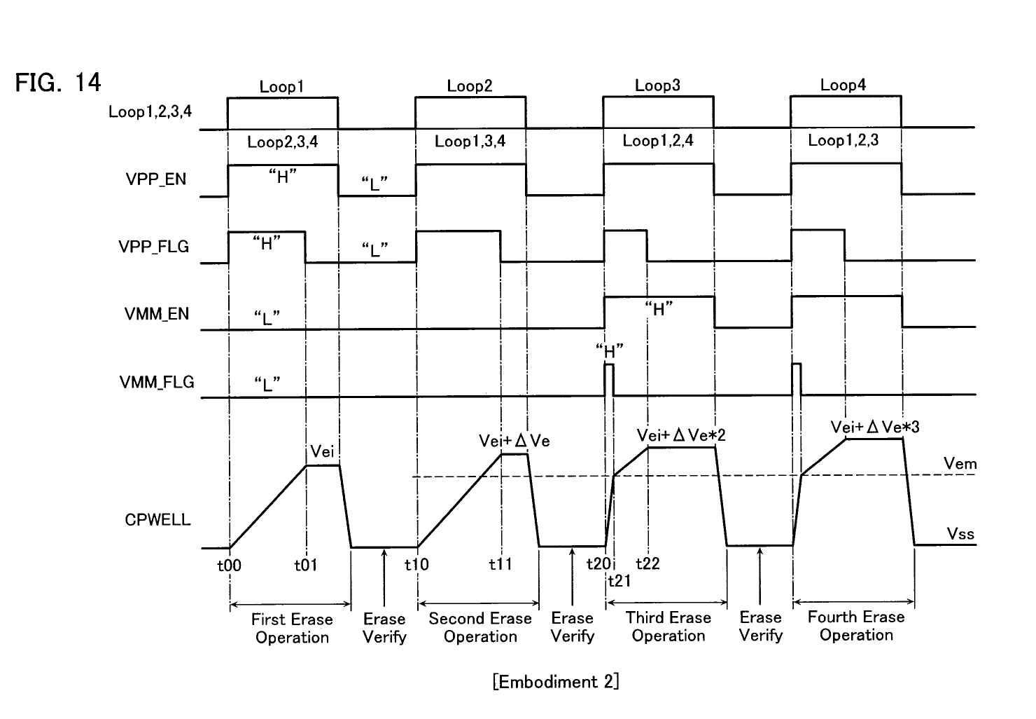

FIG. 14 shows operation waveforms in a data erase mode in accordance with embodiment 2 that takes the above point into account. The operation waveforms thereof corresponds to those of embodiment 1 in FIG. 13. The difference between embodiment 2 and embodiment 1 lies in the second erase operation.

Since circuit configurations and the first, third, and fourth erase operations in embodiment 2 are similar to those of the previous embodiment 1, descriptions thereof are omitted, and the second erase operation is described. In the second erase operation, Loop2 of the loop signals is “H”, and Loop1, Loop3, and Loop4 are “L”.

In the VPP-dedicated voltage detecting circuit DET1, the NMOS transistor MN34 is turned on due to the NAND gate G16, which has as inputs the activating signal VPP_EN and the signal Loop2, and the inverter G20. In addition, the NMOS transistor MN37 is turned on.

Even though the second erase operation is started, the VMM-dedicated pump activating signal VMM_EN maintains “L”, and the second boost operation also is performed only by the VPP-dedicated pump PMP1 (timing t10). The VPP-dedicated voltage detecting circuit DET1 outputs the detecting signal VPP_FLG=″H″ so as to boost the voltage VPP until the setting voltage is attained.

The boost potential VPP is supplied, via the NMOS transistor MN11 that has its gate applied with a boost potential by the local pump LPMP1, to the terminal CPWELL. When the voltage VPP and the potential of the terminal CPWELL reach the setting potential Vei+ΔVe, VPP_FLG attains “L”, whereby the boost operation is suspended (timing t11).

Consequently, in the second erase operation, the rise waveform of the potential of the terminal CPWELL is less steep and the boost time of the potential of the terminal CPWELL is also longer than in the comparative example, similarly to the first erase operation in embodiment 1. This allows the electrons to be discharged slowly from the floating gate FG also during the second erase operation. That is, the amount of current that crosses the tunnel insulating film is maintained small, whereby deterioration of the tunnel insulating film can be suppressed.

The third and subsequent erase operations are the same as the second and subsequent erase operations of the previous embodiment. That is, the VPP-dedicated pump PMP1 and the VMM-dedicated pump PMP2 start operation concurrently (timing t20), perform a high speed boost. When the boost potential reaches the setting voltage Vem, the VMM_FLG attains “L”, whereby the VMM-dedicated pump PMP2 suspends operation (timing t21). When the boost potential attains Vei+ΔVex2, the VPP-dedicated pump PMP1 suspends operation (timing t22).

As described above, in this embodiment 2, the electrons are discharged slowly from the floating gate FG during the first and second erase operations which are the operations that cause most deterioration of the tunnel insulating film. As a result, the amount of current that crosses the tunnel insulating film is maintained small, whereby deterioration of the tunnel insulating film can be minimized. At the same time, extension of the erase operation time in the third and subsequent erase operations can be suppressed, enabling the time taken for the erase operation to be made equal to that of a conventional erase operation.

### Embodiment 3

In the embodiments up to now, the two sets of pump circuit are controlled such that only the pump circuit having low current supply capability but capable of generating a high voltage is operated in the initial stage of the erase cycle. This may suppress the erase current and prevents deterioration of cell characteristics. On the other hand, a similar effect can also be obtained by driving both pump circuits of the two-system pump circuit concurrently. To do so requires only to set the current supply capability of the pump circuits itself to be switchable, and to perform switching of pump capability in accordance with the erase cycle.

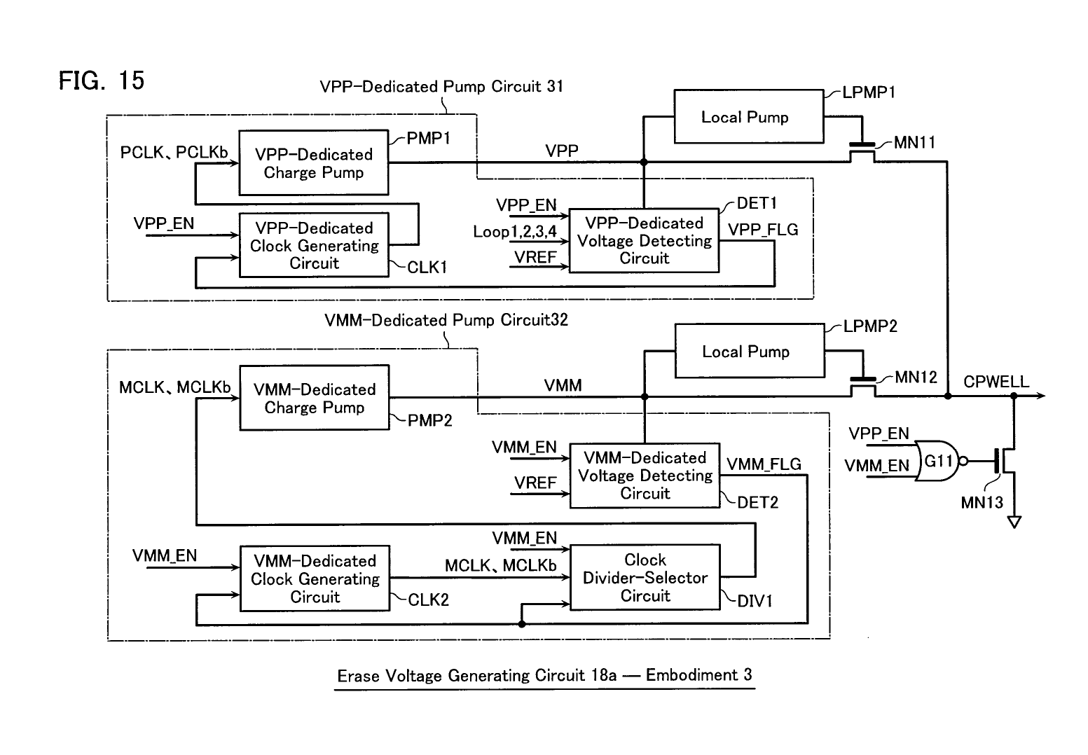

FIG. 15 shows a configuration of an erase voltage generating circuit 18a employed in such an embodiment 3, corresponding to FIG. 3. The erase voltage generating circuit 18a shown in FIG. 15 differs from that shown in FIG. 3 in having a clock divider-selector circuit DIV1 in the VMM-dedicated pump circuit 32 for switching the drive clock frequency of the VMM-dedicated pump circuit 32.

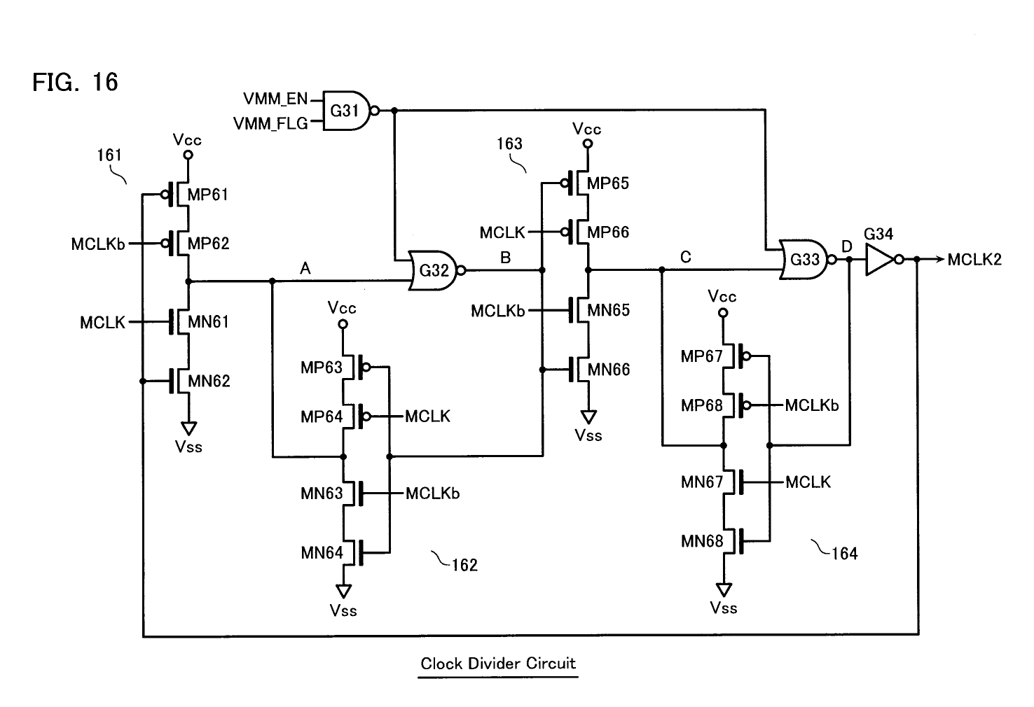

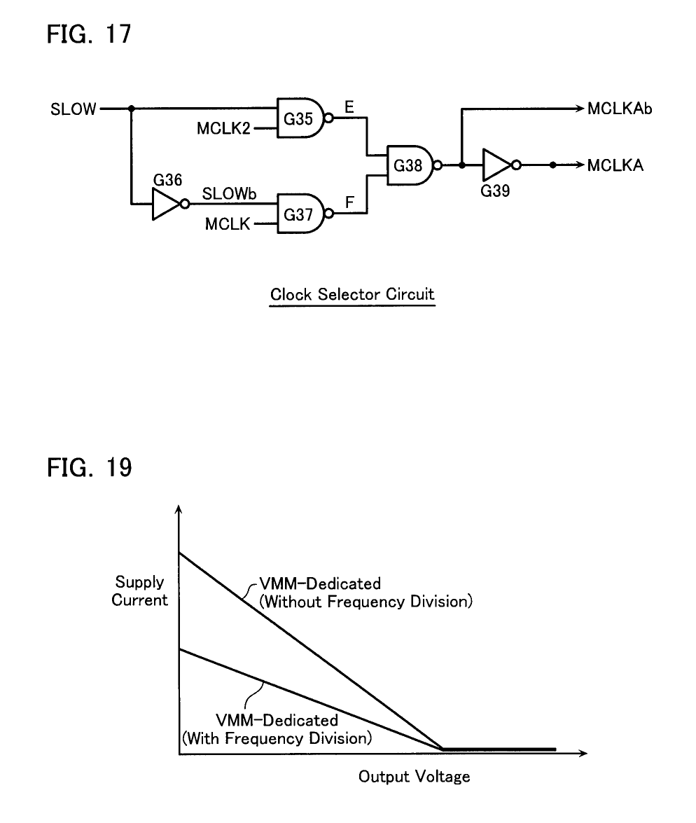

FIG. 16 shows a configuration of a clock divider circuit of the clock divider-selector circuit DIV1, and FIG. 17 shows similarly a configuration of a clock selector circuit of the clock divider-selector circuit DIV1.

The clock divider circuit includes CMOS inverters 161, and 162. The CMOS inverters 161 has inputs of complementary clocks MCLK/MCLKb. The CMOS inverter 162 shares an output node A of the CMOS inverter 161. The CMOS inverters 162 is inputted with a reverse phase to that of the inverter 161, and is configured to control the output node A in accordance with output of a NOR gate G32.

Furthermore, the clock divider circuit includes CMOS inverters 163, and 164. The CMOS inverter 163 is controlled by the NOR gate G32 and having inputs of complementary clocks MCLK/MCLKb. The CMOS inverter 164 is inputted with a reverse phase to that of the inverter 161. The CMOS inverters 164 is configured to control a state of an output node C of the CMOS inverter 163 in accordance with output of a NOR gate G33.

An output node D of the NOR gate G33 is linked via an inverter G34 to an output node of clock MCLK2, output node of the clock MCLK2 forming a control signal of the CMOS inverter 161.

When the activating signals VMM_EN and VMM_FLG are concurrently “H”, this is detected by a NAND gate G31 which thus outputs “L”, this output “L” of the NAND gate G31 causing the NOR gates G32 and G33 to be activated and operate as inverters. That is, when the activating signals VMM_EN and VMM_FLG are concurrently “H”, the NOR gates G32 and G33 are activated causing the frequency dividing circuit to operate, and thereby output clock MCLK2, which is a frequency divided clock MCLK. If either of the activating signals VMM_EN and VMM_FLG is “L”, output of the NOR gates G32 and G33 is fixed at “L”, whereby the frequency dividing circuit does not operate.

The clock selector circuit is a circuit for selecting clock MCLK2, which is frequency divided, or clock MCLK, which is not frequency divided, based on a selecting signal SLOW generated from the controller 19. That is, the clock selector circuit includes NAND gates G37 and G35 having as inputs clocks MCLK and MCLK2, respectively, the NAND gates G37 and G35 being selectively activated by the selecting signal SLOW. Complementary signals MCLKA and MCLKAb are generated by a NAND gate G38 and an inverter G39, based on output of the NAND gates G37 and G35.

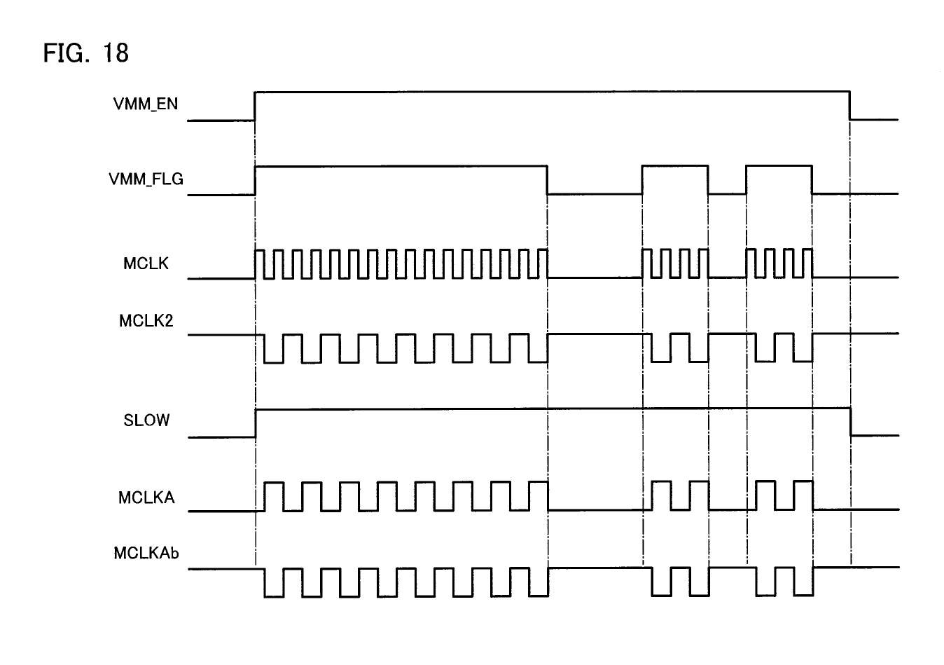

Operation of the clock divider-selector circuit is described specifically with reference to FIG. 18.

When the activating signals VMM_EN and VMM_FLG are concurrently “H”, the NOR gates G32 and G33 are activated causing the frequency dividing circuit to operate. At this time, the VMM-dedicated clock generating circuit CLK2 also starts to operate, whereby the complementary signals MCLK/MCLKb are generated. The frequency dividing operation is as follows.

When the signal MCLK changes from “L” to “H”, MCLK=“H” and MCLKb=“L” are inputted to the NMOS transistor MN61 and the PMOS transistor MP62, respectively, whereby output node A of the inverter 161 attains “L”. At this time, the inverter 163 is reverse-inputted, whereby the potential of output node C is undetermined.

Meanwhile, in the inverter 164, the initial state “L” of node D causes the PMOS transistor MP67 to be turned on and the NMOS transistor MN68 to be turned off, and, since the PMOS transistor MP68 is turned on due to MCLKb=“L”, the inverter 164 causes node C to be set to “H”.

Next, when the signal MCLK shifts to “L” and the signal MCLKb shifts to “H”, the inverter 162 causes the output node A to maintain “L” state, and the inverter 163 causes output node C of the inverter 163 to attain “L”. Since inputs of the NOR gate G33 are concurrently “L”, node D shifts to “H”, and MCLK2 consequently shifts to “L”.

Next, when the signal MCLK attains “H”, the inverter 164 causes node C to maintain “L” state, and, since inputs of the NOR gate G33 remain concurrently “L”, node D maintains “H” and signal MCLK2 maintains “L”. On the other hand, in the inverter 161, the NMOS transistors MN61 and MN62 are turned on, whereby output node A shifts to “L” and node B shifts to “H”.

When signal MCLK again attains “L”, the PMOS transistors MP65 and MP66 in the inverter 163 are turned on, output node C of the inverter 163 attains “H” and node D attains “L”, and MCLK2 attains “H”.

Repetition of such an operation allows a clock MCLK2 to be obtained which is a frequency-divided clock MCLK and has a period twice that of clock MCLK.

Next, operation of the clock selector circuit is described. When the selecting signal SLOW generated by the erase voltage generating circuit is “H”, the NAND gate G35 is activated, and when SLOW=“L”, the NAND gate G37 is activated.

Since inputs of the NAND gate G37 are signal SLOWb and signal MCLK, when SLOWb=“L”, output F is maintained at “H”, irrespective of signal MCLK. On the other hand, since inputs of NAND gate G35 are signal SLOW and signal MCLK2, when SLOW=“H”, output E of the NAND gate G35 attains the inverted signal of signal MCLK2.

The NAND gate G38 has E and F as inputs, and therefore, when F is “H”, outputs as MCLKAb the inverted signal of E, that is, a signal having the same phase as signal MCLK2. The inverter G39 has signal MCLKAb as input, and outputs its inverted signal MCLKA.

Accordingly, when SLOW=“H”, the clock selector circuit outputs signal MCLK2 having a period twice that of signal MCLK as complementary signals MCLKA/MCLKAb. When SLOW=″L″, the NAND gate G37 outputs the inverted signal of signal MCLK.

The complementary signals MCLKA/MCLKAb are inputted to the VMM-dedicated charge pump PMP2. That is, it becomes possible to select pump drive by a non-frequency-divided clock and pump drive by a frequency-divided clock according to SLOW signal.

FIG. 19 shows current supply capability of the VMM-dedicated pump PMP2 compared for cases where the clock is not frequency divided and where the clock is frequency divided. Basic operation of the charge pump is unrelated to clock frequency. However, the number of times the boost operation is performed per certain unit time in the case of frequency division is half that in the case of no frequency division. Therefore, the current supply capability with respect to the same output voltage is also halved in the case where a frequency divided clock is employed.

Performing clock frequency control of the pump drive as described above enables current supply capability of the pump to be controlled and makes possible control to selectively make the rise waveform of the erase voltage less steep.

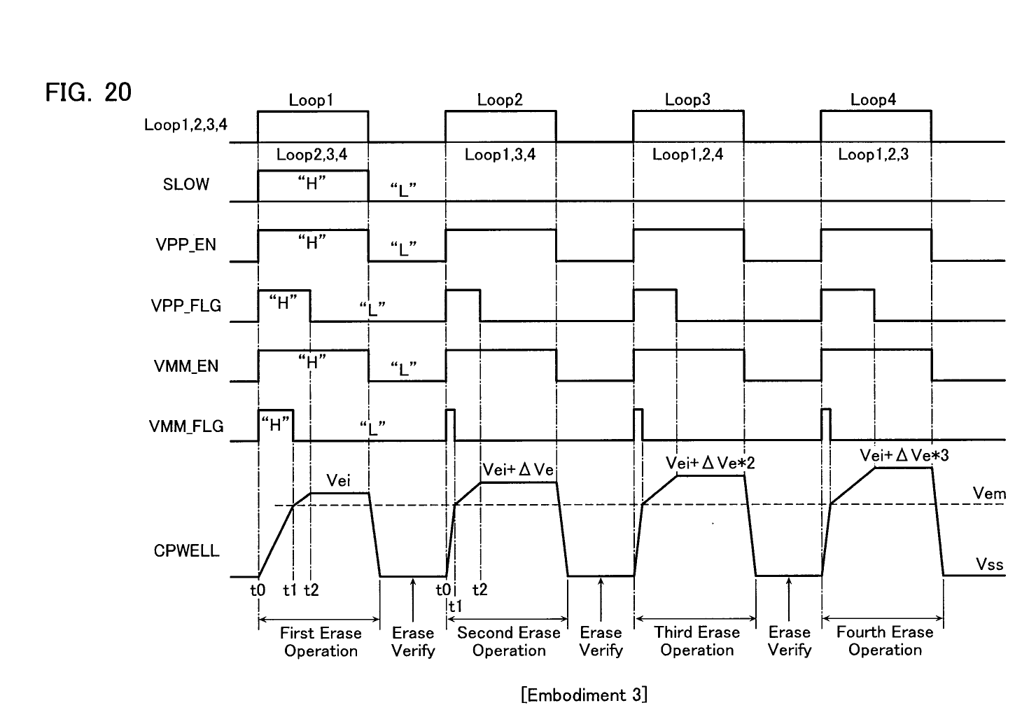

FIG. 20 shows operation waveforms of the data erase mode in accordance with embodiment 3, corresponding to the embodiments of FIGS. 13 and 14. Basic operation of embodiment 3 is similar to that of embodiment 1 and detailed description thereof is thus omitted. However, the erase voltage rise waveform in the first erase operation of embodiment 3 differs from that of embodiment 1. In comparison with the comparative example of FIG. 27, the erase voltage rise waveform of embodiment 3 is less steep and the time taken to reach Vem, that is, time t1-t0, differs.

This is described specifically. When the first erase operation starts (timing t0), the signals Loop1, VPP_EN, VMM_EN, and SLOW attain “H”. At this time, the two pumps PMP1 and PMP2 start operation simultaneously. However, due to SLOW=“H”, the clock divider-selector circuit DIV1 outputs the clock signal MCLK2, which is a frequency-divided pump clock MCLK, as the complementary signals MCLKA/MCLKAb. Therefore, in the VMM-dedicated charge pump PMP2, the boost operation is performed by the complementary signals MCLKA/MCLKAb.

Since, in this case, current supply capability with respect to output voltage of the pump is set to half of normal as shown in FIG. 19, the time t0-t1 taken for the voltage VMM and the potential of the terminal CPWELL to be boosted to the setting potential Vem becomes two times or more longer than normal. That is, the rise waveform of the initial erase voltage becomes less steep.

Operation control of this kind enables deterioration of the tunnel insulating film during the first erase operation to be suppressed.

In the second, third, and fourth erase operations, SLOW=“L”, and the clock divider-selector circuit DIV1 outputs the pump clock MCLK to the VMM-dedicated charge pump PMP2 as the complementary signals MCLKA/MCLKAb. At this time, the pump capability is the same as in previous embodiment 1, the boost time t1-t0 of the potential of the terminal CPWELL is reduced, and the boost speed is faster than in the first erase operation.

In order to discharge electrons in the second erase operation that were not discharged in the first erase operation, the potential of the terminal CPWELL is boosted to Vei+ΔVe which is higher than in the first erase operation. There is a possibility that the time taken for the boost operation becomes longer than in the first erase operation, but the present embodiment enables extension of the time to be suppressed. Likewise regarding the third and fourth erase operations, extension of the time for the erase operation can be similarly suppressed.

Operation as described above allows deterioration of the tunnel insulating film to be minimized, without impairing high speed of the erase operation.

### Embodiment 4

There are cases where, in the first erase operation, almost no electrons in the floating gate FG are discharged, such as when the erase voltage Vei is set low, or when the erase time is short. During the second erase operation, the erase voltage is set to the voltage Vei+ΔVe which is higher than the voltage Vei of the first erase operation, and the electrons thus become more easily discharged. Consequently, there is a possibility that the amount of current crossing the tunnel insulating film during the second erase operation becomes large, whereby the tunnel insulating film deteriorates.

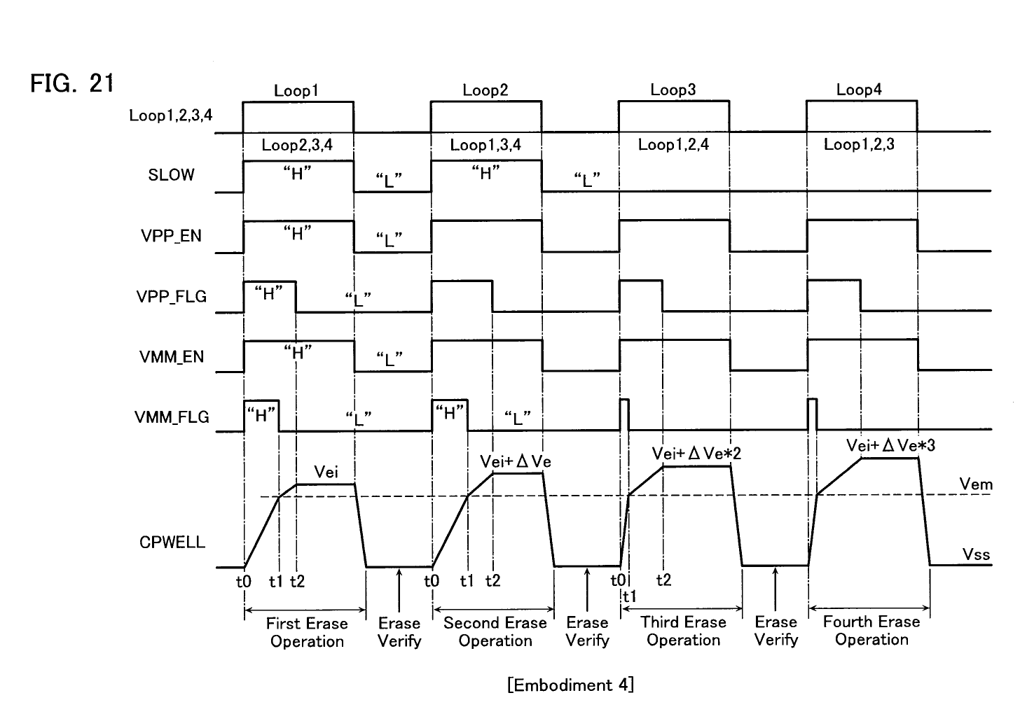

FIG. 21 shows operation voltage waveforms in embodiment 4, which is embodiment 3 slightly modified to take the above point into account. The difference between embodiment 4 and embodiment 3 lies in the second erase operation.

Since circuit configurations and the first, third, and fourth erase operations in embodiment 4 are the same as those of the previous embodiment 3, descriptions thereof are omitted. In this embodiment 4, SLOW is set to “H” and a frequency-divided clock is applied to the VMM-dedicated pump PMP2 also in the second erase operation.

That is, the VMM-dedicated charge pump PMP2 performs the boost operation by the complementary signals MCLKA/MCLKAb in the second erase operation, similarly to the first erase operation, thereby making the rise in the boost voltage less steep. That is, the boost time to Vem, namely boost time t1-t0, is set longer than normal in both the first and second erase operations, this boost time t1-t0 being reduced from the third erase operation.

This enables deterioration of the tunnel insulating film in the second erase operation to be suppressed, and allows extension of total time taken for the erase operation to be suppressed to an insignificant level.

### Embodiment 5

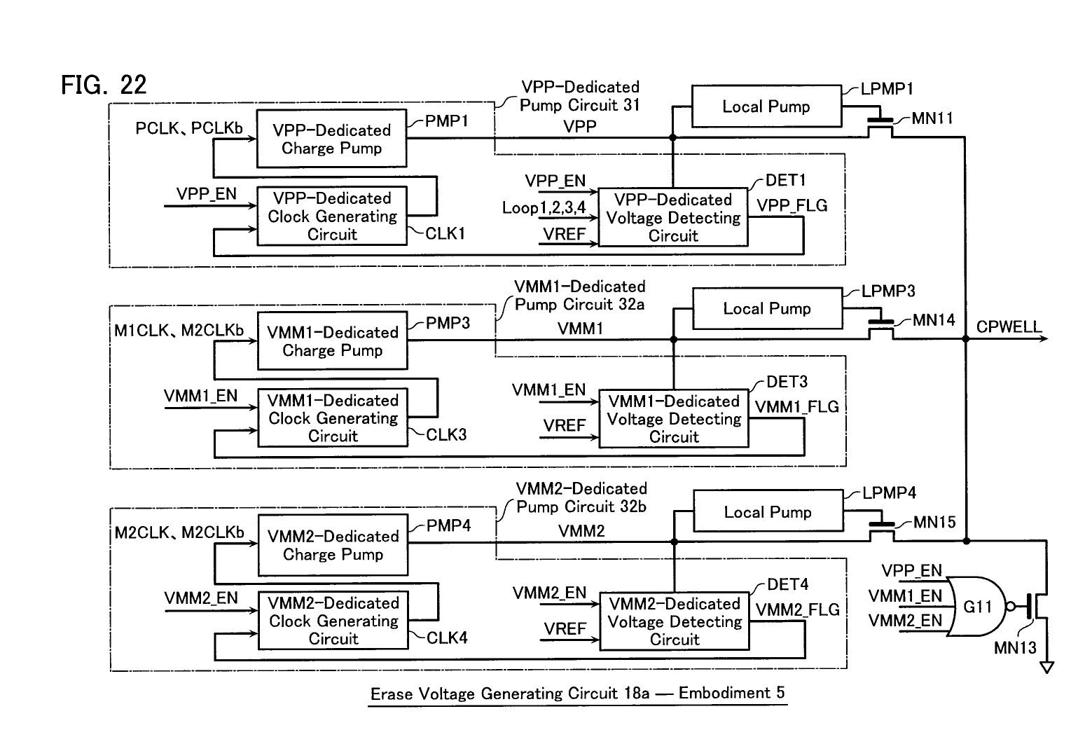

FIG. 22 shows a configuration of an erase voltage generating circuit 18a employed in an embodiment 5. In this embodiment 5, two pump circuits, that is, a VMM1-dedicated pump circuit 32a and a VMM2-dedicated pump circuit 32b are provided in parallel to the VMM-dedicated charge pump circuit 32 portion described in the embodiments up to now.

The VMM1-dedicated pump circuit 32a includes a charge pump PMP3, a clock generating circuit CLK3, and a voltage detecting circuit DET3. The VMM2-dedicated pump circuit 32b similarly includes a charge pump PMP4, a clock generating circuit CLK4, and a voltage detecting circuit DET4. In addition, the VMM1-dedicated pump circuit 32a and VMM2-dedicated pump circuit 32b have local pumps LPMP3 and LPMP4 attached thereto, respectively, and have outputs commonly connected to the terminal CPWELL.

These two pump circuits 32a and 32b have configurations and capabilities that are the same, excepting that they are activation controlled separately by activating signals VMM1_EN and VMM2_EN.

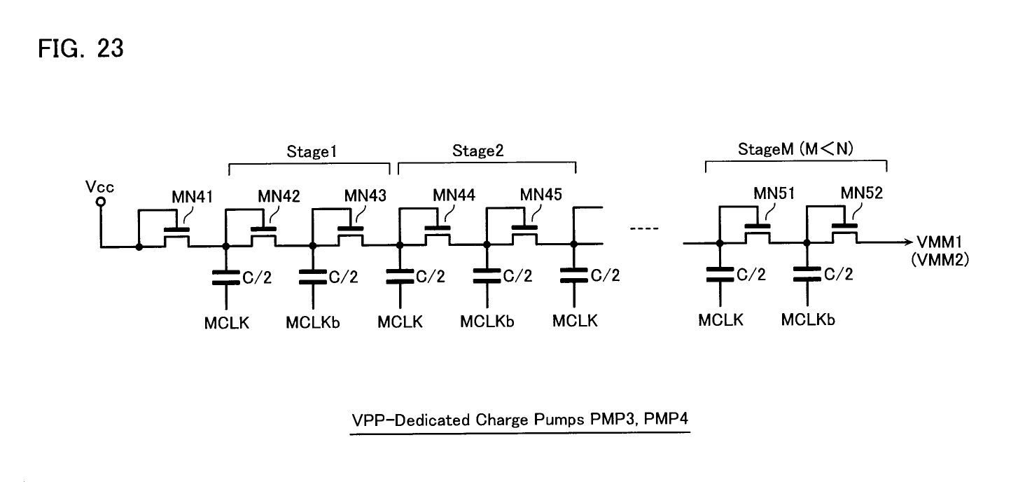

FIG. 23 shows a configuration of the charge pump circuits PMP3 and PMP4. The basic configuration is unchanged from that of the VMM-dedicated charge pump PMP2 of the previous embodiment shown in FIG. 8. The charge pump circuits PMP3 and PMP4 differ from the previous charge pump PMP2 in having a capacitance of the boost capacitor which is half that of the previous charge pump PMP2.

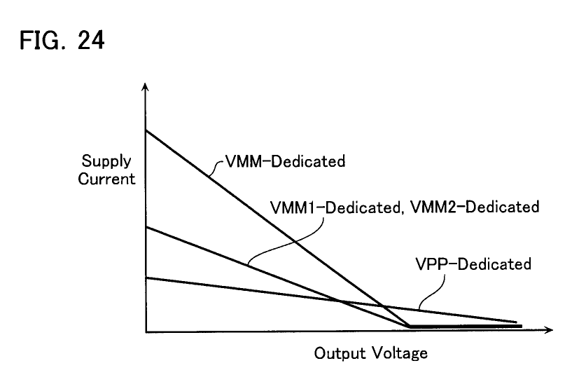

Consequently, as shown in FIG. 24, the current supply capability of the VMM1-dedicated and VMM2-dedicated pumps is half that of the VMM-dedicated pumps of previous embodiments. This leads to pump capability being selectable by switching control to either use the charge pumps PMP3 and PMP4 simultaneously, or to use one only. That is, control is enabled which makes the erase voltage rise waveform less steep in the initial stage of the erase cycles, similarly to the previous embodiments.

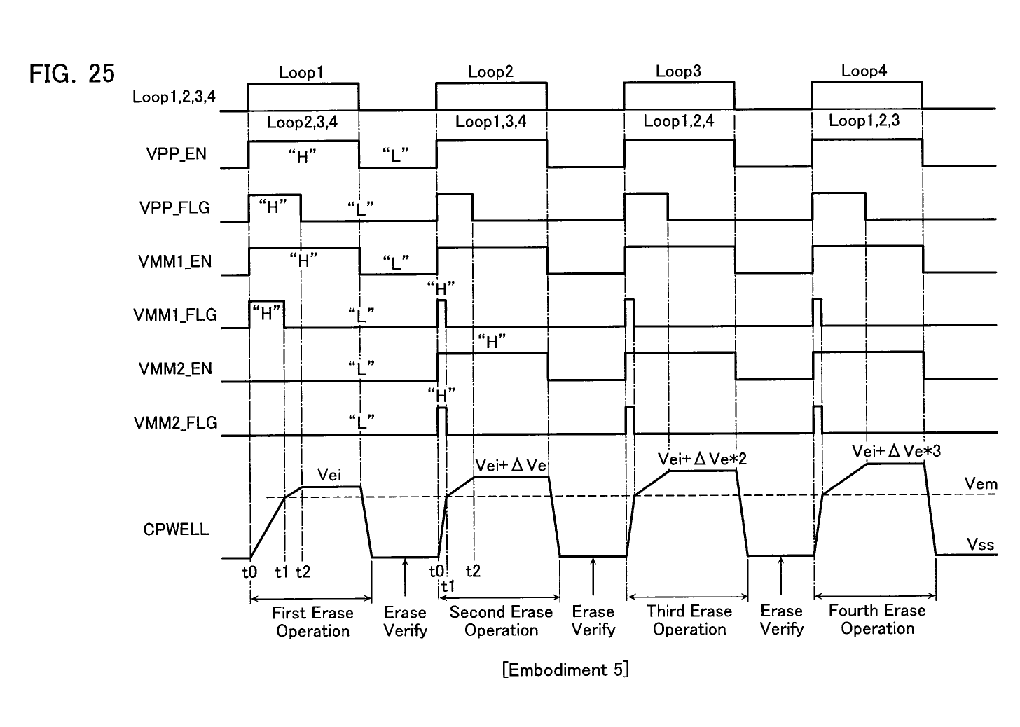

FIG. 25 shows waveforms of the erase operation in this embodiment. Basic operation is similar to that of previous embodiments and detailed description thereof is thus omitted. However, the boost time t1-t0 which is the time taken for the potential of the terminal CPWELL to reach the setting potential Vem in the first erase operation is equal to that in embodiment 3.

In the first erase operation, the signals Loop1, VPP_EN, and VMM1_EN attain “H”. This causes the VPP-dedicated pump PMP1 and the VMM1-dedicated pump PMP3 to each start the boost operation. On the other hand, the signal VMM2_EN remains at “L”, whereby the VMM2-dedicated pump PMP4 does not operate.

This causes the erase voltage rise waveform in the first erase operation to be less steep, thereby enabling deterioration of the tunnel insulating film to be suppressed.

In the second, third, and fourth erase operations, the signals VPP_EN, VMM1_EN, and VMM2_EN all attain “H”. That is, the VMM1-dedicated pump PMP3 and VMM2-dedicated pump PMP4 both operate simultaneously with the VPP-dedicated pump PMP1. As a result, the time t1-t0 which is the time taken for the potential of the terminal CPWELL to reach the Vem potential is reduced, whereby the second, third, and fourth erase operations become faster than the first erase operation.

For example, in order to discharge electrons in the second erase operation that were not discharged in the first erase operation, the potential of the terminal CPWELL is boosted to Vei+ΔVe which is higher than in the first erase operation. There is a possibility that the time taken for the boost operation becomes longer than in the first erase operation, but such an extension of the time can be suppressed to an insignificant level.

The above-described operation enables the deterioration in cell characteristics accompanying the erase operation to be suppressed, without impairing high speed.

### Embodiment 6

There are cases where, in the first erase operation, almost no electrons in the floating gate FG are discharged, such as when the erase voltage Vei is set low, or when the erase time is short. During the second erase operation, the erase voltage is set to the voltage Vei+ΔVe which is higher than the voltage Vei of the first erase operation, and the electrons thus become more easily discharged. Consequently, there is a possibility that the amount of current crossing the tunnel insulating film during the second erase operation becomes large, whereby the tunnel insulating film deteriorates.

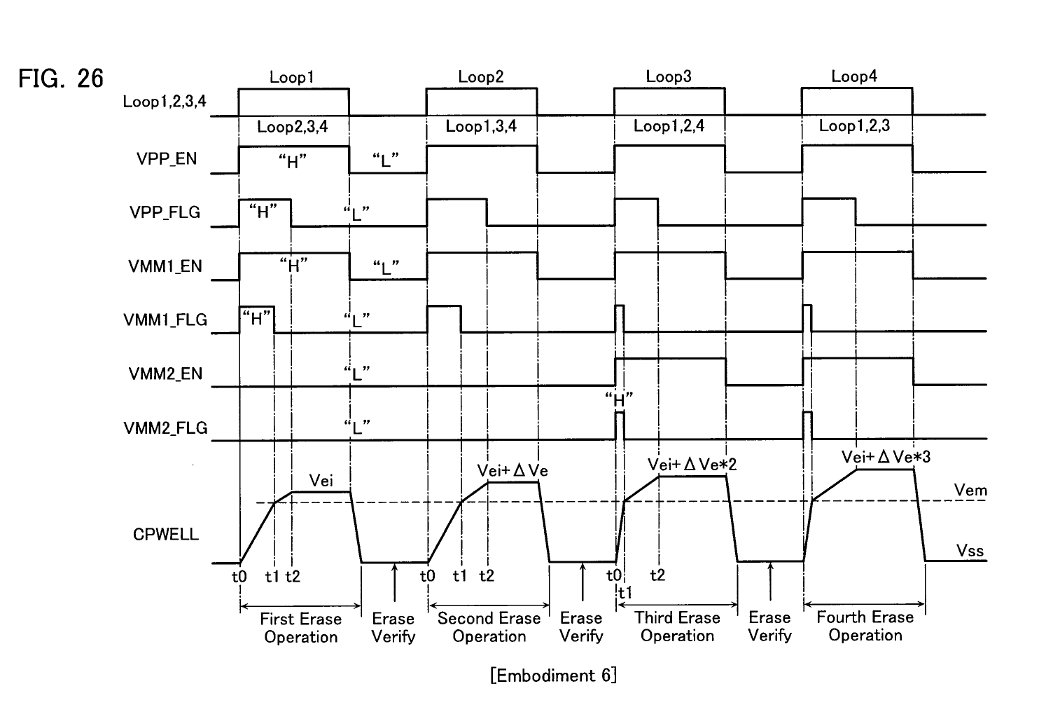

FIG. 26 shows operation voltage waveforms in embodiment 6, which is embodiment 5 slightly modified to take the above point into account. The difference between embodiment 6 and embodiment 5 lies in the second erase operation.

Since circuit configurations and the first, third, and fourth erase operations in embodiment 6 are the same as those of the previous embodiment 5, descriptions thereof are omitted. In this embodiment, the signal VMM2_EN maintains “L” in the second erase operation. That is, the VMM2-dedicated pump PMP4 does not operate in the second erase operation either. This causes the time t1-t0 required for the potential of the terminal CPWELL to be boosted to the setting potential Vem to be longer than normal in both the first and second erase operations.

As a result, deterioration of the tunnel insulating film in the second erase operation can be suppressed. Moreover, extension of the total time taken for the erase can be suppressed to an insignificant level.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, in the embodiments, which adopt an example where the erase cycle is completed in four loops, deterioration of cell characteristics accompanying the erase operation is prevented by making the erase voltage rise waveform less steep in the first loop or first and second loops, the first loop or first and second loops being regarded as the initial stage of the erase cycle.

Depending on the number of erase cycles, it is also effective to set the number of loops in the initial stage where the erase voltage boost curve is made less steep to be three or more. That is, when a large number of erase cycles is set, it is still possible to suppress deterioration of cell characteristics without significantly impairing high speed of the erase operation, even if the number of initial stage loops over which the boost time is accordingly spread is set to be high.

In addition, in embodiments 3 and 4, the example is given where the clock frequency division ratio is a half, but a third, a quarter, and so on, may be selected.

In embodiments 5 and 6, the example is shown where one of two-VMM-dedicated pump circuits 32a and 32b is employed in the initial stage and both are employed in subsequent cycles, but in practice a plurality of each of these pump circuits may be provided in parallel. For example, a specification is possible in which a total of ten VMM-dedicated pump circuits are provided in parallel, an appropriate number of these only are selected in the initial stage, and all are selected in subsequent cycles.

What is claimed is:

1. A semiconductor memory device, comprising:
a memory cell array configured as an arrangement of nonvolatile memory cells; and
an erase voltage generating circuit configured to generate an erase voltage for performing data erase of the memory cell array,
the erase voltage generating circuit being configured to set, in a data erase mode where the erase voltage is applied to a selected region of the memory cell array in a plurality of erase cycles, a rise waveform of the erase voltage in an initial stage of the plurality of erase cycles to be less steep than a rise waveform of the erase voltage in subsequent cycles.

2. The semiconductor memory device according to claim 1, wherein
the erase voltage generating circuit includes:
a first boost pump circuit; and
a second boost pump circuit provided in parallel with the first boost pump circuit and configured to generate a potential lower than that generated by the first boost pump circuit, the second boost pump circuit having a current supplying capability during rise of the erase voltage higher than that of the first boost pump circuit, and
in the data erase mode, the erase voltage generating circuit is controlled such that in the initial stage of the plurality of erase cycles only the first boost pump circuit is operated, and such that in the subsequent cycles the first and second boost pump circuits are simultaneously operated.

3. The semiconductor memory device according to claim 1, wherein
the erase voltage generating circuit includes:
a first boost pump circuit;
a second boost pump circuit provided in parallel with the first boost pump circuit and configured to generate a potential lower than that generated by the first boost pump circuit, the second boost pump circuit having a current supplying capability during rise of the erase voltage higher than that of the first boost pump circuit; and
a divider-selector circuit configured to switch a drive clock frequency of the second boost pump circuit, and
in the data erase mode, the erase voltage generating circuit is controlled such that in the initial stage of the plurality of erase cycles the first and second boost pump circuits are simultaneously operated, and such that in the subsequent cycles the first and second boost pump circuits are simultaneously operated, the second boost pump circuit being operated in the initial stage of the plurality of stages in a state where the drive clock is frequency divided, and the second boost pump circuit being operated in the subsequent cycles in a state where the drive clock is not frequency divided.

4. The semiconductor memory device according to claim 1, wherein
the erase voltage generating circuit includes:
a first boost pump circuit; and
second and third boost pump circuits,
the second and third boost pump circuits each being provided in parallel with the first boost pump circuit and being configured to generate a potential lower than that generated by the first boost pump circuit, and
in the data erase mode, the erase voltage generating circuit is controlled such that in the initial stage of the plurality of erase cycles the first boost pump circuit and one of the second and third boost pump circuits are simultaneously operated, and such that in the subsequent cycles the first boost pump circuit and the second and third boost pump circuits are simultaneously operated.

5. The semiconductor memory device according to claim 1, wherein
the erase voltage generating circuit includes:
a first boost pump circuit; and
X (x≧3) second boost pump circuits each being provided in parallel with the first boost pump circuit and being configured to generate a potential lower than that generated by the first boost pump circuit, and
in the data erase mode, the erase voltage generating circuit is controlled such that in the initial stage of the plurality of erase cycles the first boost pump circuit and Y (1≦Y≦X) of the second boost pump circuits are simultaneously operated, and such that in the subsequent cycles the first boost pump circuit and the X second boost pump circuits are simultaneously operated.

6. The semiconductor memory device according to claim 2, wherein
the first boost pump circuit includes a charge pump having N stages of boost units connected in series, and
the second boost pump circuit includes a charge pump having M (M<N) stages of boost units connected in series.

7. The semiconductor memory device according to claim 3, wherein
the first boost pump circuit includes a charge pump having N stages of boost units connected in series, and
the second boost pump circuit includes a charge pump having M (M<N) stages of boost units connected in series.

8. The semiconductor memory device according to claim 4, wherein
the first boost pump circuit includes a charge pump having N stages of boost units connected in series, and
the second boost pump circuit and the third boost pump circuit each includes a charge pump having M (M<N) stages of boost units connected in series.

9. A semiconductor device, comprising an erase voltage generating circuit configured to generate an erase voltage for performing data erase of a memory cell array, the memory cell array configured as an arrangement of nonvolatile memory cells,
the erase voltage generating circuit being configured to set, in a data erase mode where the erase voltage is applied to a selected region of the memory cell array in a plurality of erase cycles, a rise waveform of the erase voltage in an initial stage of the plurality of erase cycles to be less steep than a rise waveform of the erase voltage in subsequent cycles.

10. The semiconductor device according to claim 9, wherein
the erase voltage generating circuit includes:
a first boost pump circuit; and
a second boost pump circuit provided in parallel with the first boost pump circuit and configured to generate a potential lower than that generated by the first boost pump circuit, the second boost pump circuit having a current supplying capability during rise of the erase voltage higher than that of the first boost pump circuit, and
in the data erase mode, the erase voltage generating circuit is controlled such that in the initial stage of the plurality of erase cycles only the first boost pump circuit is operated, and such that in the subsequent cycles the first and second boost pump circuits are simultaneously operated.

11. The semiconductor device according to claim 9, wherein
the erase voltage generating circuit includes:
a first boost pump circuit;
a second boost pump circuit provided in parallel with the first boost pump circuit and configured to generate a potential lower than that generated by the first boost pump circuit, the second boost pump circuit having a current supplying capability during rise of the erase voltage higher than that of the first boost pump circuit; and
a divider-selector circuit configured to switch a drive clock frequency of the second boost pump circuit, and
in the data erase mode, the erase voltage generating circuit is controlled such that in the initial stage of the plurality of erase cycles the first and second boost pump circuits are simultaneously operated, and such that in the subsequent cycles the first and second boost pump circuits are simultaneously operated, the second boost pump circuit being operated in the initial stage of the plurality of stages in a state where the drive clock is frequency divided, and the second boost pump circuit being operated in the subsequent cycles in a state where the drive clock is not frequency divided.

12. The semiconductor device according to claim 9, wherein
the erase voltage generating circuit includes:
a first boost pump circuit; and
second and third boost pump circuits,
the second and third boost pump circuits each being provided in parallel with the first boost pump circuit and being configured to generate a potential lower than that generated by the first boost pump circuit, and
in the data erase mode, the erase voltage generating circuit is controlled such that in the initial stage of the plurality of erase cycles the first boost pump circuit and one of the second and third boost pump circuits are simultaneously operated, and such that in the subsequent cycles the first boost pump circuit and the second and third boost pump circuits are simultaneously operated.

13. The semiconductor device according to claim 9, wherein
the erase voltage generating circuit includes:
a first boost pump circuit; and
X (X≧3) second boost pump circuits each being provided in parallel with the first boost pump circuit and being configured to generate a potential lower than that generated by the first boost pump circuit, and
in the data erase mode, the erase voltage generating circuit is controlled such that in the initial stage of the plurality of erase cycles the first boost pump circuit and Y (1≦Y≦X) of the second boost pump circuits are simultaneously operated, and such that in the subsequent cycles the first boost pump circuit and the X second boost pump circuits are simultaneously operated.

14. The semiconductor device according to claim 10, wherein
the first boost pump circuit includes a charge pump having N stages of boost units connected in series, and
the second boost pump circuit includes a charge pump having M (M<N) stages of boost units connected in series.

15. The semiconductor device according to claim 11, wherein
the first boost pump circuit includes a charge pump having N stages of boost units connected in series, and
the second boost pump circuit includes a charge pump having M (M<N) stages of boost units connected in series.

16. A method of data erase in a semiconductor memory device, comprising:
generating an erase voltage for performing data erase of a memory cell array, the memory cell array being configured as an arrangement of nonvolatile memory cells; and
in a data erase mode where the erase voltage is applied to a selected region of the memory cell array in a plurality of erase cycles, setting a rise waveform of the erase voltage in an initial stage of the plurality of erase cycles to be less steep than a rise waveform of the erase voltage in subsequent cycles.

17. The method of data erase according to claim 16, further comprising:
employing: a first boost pump circuit; and a second boost pump circuit provided in parallel with the first boost pump circuit and configured to generate a potential lower than that generated by the first boost pump circuit, the second boost pump circuit having a current supplying capability during rise of the erase voltage higher than that of the first boost pump circuit; and
in the data erase mode, controlling such that in the initial stage of the plurality of erase cycles only the first boost pump circuit is operated, and such that in the subsequent cycles the first and second boost pump circuits are simultaneously operated.

18. The method of data erase according to claim 16, further comprising:
employing: a first boost pump circuit; a second boost pump circuit provided in parallel with the first boost pump circuit and configured to generate a potential lower than that generated by the first boost pump circuit, the second boost pump circuit having a current supplying capability during rise of the erase voltage higher than that of the first boost pump circuit; and a divider-selector circuit configured to switch a drive clock frequency of the second boost pump circuit; and
in the data erase mode, controlling such that in the initial stage of the plurality of erase cycles the first and second boost pump circuits are simultaneously operated, and such that in the subsequent cycles the first and second boost pump circuits are simultaneously operated, the second boost pump circuit being operated in the initial stage of the plurality of stages in a state where the drive clock is frequency divided, and the second boost pump circuit being operated in the subsequent cycles in a state where the drive clock is not frequency divided.

19. The method of data erase according to claim 16, further comprising:
Employing: a first boost pump circuit; and second and third boost pump circuits, the second and third boost pump circuits each being provided in parallel with the first boost pump circuit and being configured to generate a potential lower than that generated by the first boost pump circuit; and
in the data erase mode, controlling such that in the initial stage of the plurality of erase cycles the first boost pump circuit and one of the second and third boost pump circuits are simultaneously operated, and such that in the subsequent cycles the first boost pump circuit and the second and third boost pump circuits are simultaneously operated.

20. The method of data erase according to claim 16, further comprising:
employing: a first boost pump circuit; and X (X≧3) second boost pump circuits each being provided in parallel with the first boost pump circuit and being configured to generate a potential is lower than that generated by the first boost pump circuit; and
in the data erase mode, controlling such that in the initial stage of the plurality of erase cycles the first boost pump circuit and Y (1≦Y≦X) of the second boost pump circuits are simultaneously operated, and such that in the subsequent cycles the first boost pump circuit and the X second boost pump circuits are simultaneously operated.
